(19) United States
(12) Patent Application Publication
(10) Pub. No.: US 2005/0141002 A1
(43) Pub. Date: Jun. 30, 2005

(54) Image-processing method, image-processing apparatus and image-recording apparatus

(75) Inventors: Hiroaki Takano, Tokyo (JP); Tsukasa Ito, Tokyo (JP); Takeshi Nakajima, Tokyo (JP); Daisuke Sato, Tokyo (JP)

Correspondence Address: MUSERLIAN, LUCAS AND MERCANTI, LLP, 475 PARK AVENUE SOUTH, 15TH FLOOR, NEW YORK, NY, 10016, US

(73) Assignee: Konica Minolta Photo Imaging, Inc.

(21) Appl. No.: 11/021,089

(22) Filed: Dec. 23, 2004

(30) Foreign Application Priority Data
Dec. 26, 2003 (JP) JP2003-434669

(51) Int. Cl. G06F 15/00; G03F 3/08

(52) U.S. Cl. 358/1.9; 382/274; 358/520

(57) ABSTRACT

An image processing method of obtaining captured image data of pixels corresponding to one image plane and outputting image data optimized for viewing on an outputting medium, comprising: a brightness value distributing process of dividing a brightness region into plural brightness regions and distributing the pixels of the captured image data in accordance with the brightness value of each pixel into one of the plural brightness regions; a color specification value distributing process of dividing a two dimensional color specification region into plural color specification regions and brightness values and distributing the pixels of the captured image data in accordance with the hue and brightness values of each pixel into one of the plural color specification regions; and a photographing scene estimating process of estimating a photographing scene of the captured image data on the basis of the calculated brightness region occupation ratio and the calculated color specification region occupation ratio.

### BACKGROUND OF THE INVENTION

The present invention relates to an image-processing method, an image-processing apparatus and an image-recording apparatus, whereby an image processing is applied to captured image data so as to output image data optimized for viewing an image reproduced on an output medium.

At present, the digital image data acquired by scanning a color photo-film or the digital image data captured by an image-capturing apparatus, such as a digital camera, etc., is distributed through such a memory device as a CD-R (Compact Disk Recordable), a floppy disk (registered trade name) and a memory card or the Internet, and is displayed on such a display monitor as a CRT (Cathode Ray Tube), a liquid crystal display and a plasma display or a small-sized liquid crystal monitor display device of a cellular phone, or is printed out as a hard copy image using such an output device as a digital printer, an inkjet printer and a thermal printer. In this way, displaying and printing methods have been diversified in recent years.

In response to such various kinds of displaying and printing methods, efforts have been made to improve the general-purpose flexibility of digital image data captured by an image-capturing apparatus. As a part of these efforts, an attempt has been made to standardize the color space represented by digital RGB (Red, Green and Blue) signals as a color space that does not depend on characteristics of an image-capturing apparatus. At present, the sRGB (refer to “Multimedia Systems and Equipment—Color Measurement and Management—Part 2-1: Color Management—Default RGB Color Space—sRGB” IEC61966-2-1) have been adopted for most of digital image data as a standardized color space. The color space of this sRGB has been established to meet the color reproduction area for a standard CRT display monitor.

Generally speaking, a scanner and a digital camera are provided with an image sensor, serving as an image-capturing device (CCD type image sensor, hereinafter also referred to as “CCD” for simplicity), which is constituted by a CCD (Charge Coupled Device), a charge transferring circuit and a mosaic-patterned color filter so as to give a color sensitivity in addition to a photoelectronic converting function.

The digital image data outputted from the scanner or the digital camera are acquired by applying correction processing of photoelectronic converting functions (for instance, a gradation correction, a spectral sensitivity, a cross-talk correction, a dark current noise control, a sharpness emphasizing, a white balance adjustment and a color saturation adjustment) of the image-capturing device to the original-electronic signals converted by the CCD, and further, by applying a file conversion/compression processing for converting the digital image data into a predetermined and standardized data format, etc., so as to allow the image editing software to execute the reading/displaying operations.

The above-mentioned data format widely known includes Baseline Tiff Rev. 6.0 RGB Full Color Image adopted as a non-compressed file of the Exif (Exchangeable Image File Format) file and compressed data file format conforming to the JPEG format. The Exif file conforms to the above-mentioned sRGB, and the correction of the photoelectric conversion function of the above-mentioned image-capturing element is established so as to ensure the most suitable image quality on the display monitor conforming to the sRGB.

For example, if a digital camera has the function of writing into the header of the digital image data the tag information for display in the standard color space (hereinafter referred to as “monitor profile”) of the display monitor conforming to the sRGB signal, and additive information indicating the device dependent information such as the number of pixels, pixel arrangement and number of bits per pixel as meta-data, and if only such a data format is adopted, then the tag information can be analyzed by the image editing software (e.g. Photoshop by Adobe for displaying the above-mentioned digital image data on the digital display monitor, conversion of the monitor profile into the sRGB can be prompted, and modification can be processed automatically. This capability reduces the differences in apparatus characteristics among different displays, and permits viewing of the digital image data photographed by a digital camera under the optimum condition.

In addition to the above-mentioned information dependent on device type, the above-mentioned additive information includes; information directly related to the camera type (device type) such as a camera name and code number, information on photographing conditions such as exposure time, shutter speed, f-stop number (F number), ISO sensitivity, brightness value, subject distance range, light source, on/off status of a stroboscopic lamp, subject area, white balance, zoom scaling factor, subject configuration, photographing scene type, the amount of reflected light of the stroboscopic lamp source and a color saturation for photographing, and tags (codes) for indicating the information related to a subject. The image editing software and output device have a function of reading the above-mentioned additive information and making the quality of hardware image more suitable.

As for the color film products, a product having a magnetic recording layer onto which the additive information can be recorded (known as the APS film) has been developed. Opposing to the expectations of the film industry concerned, however, the proliferation of APS films has bee slow in the market, and at present, the conventional film products still occupy a large share of the film market. Accordingly, it cannot be expected for the time being that the additive information is employed for the image processing to be applied to the image data read by scanning the film image. Further, since the characteristics of the color photo-films differ from kind by kind, initially-established Digital Mini Labs. had prepared various kinds of optimum processing conditions, each of which corresponds to each of the conventional film products. Recent years, however, with respect to almost all kinds of film products, such the practice have been abolished due to the improvement of the productivity. Therefore, there has increased the needs for such the highly-advanced image-processing technologies that correct the differences between various kinds of film products, and further, automatically conduct an improvement of the image quality, equivalent to that of achieved by employing the additive information, only by employing the density information of the film concerned.

Among other things, the gray (or white) balance adjustment for correcting variation of color temperature of the photographing light source, the gradation compression (or gradation conversion) processing applied to an image captured under a backlight condition or a strobe lighting condition, etc., is one of the desirable items that should be corrected at a time of image-capturing operation or should acquire information for correcting it. Although it is possible for the digital camera to compensate for the abovementioned items at the time of image-capturing operation, it is principally impossible for color film to do so. Further, since the employment of the additive information cannot be expected for the time being as mentioned in the above, there has been a very large obstacle, which impedes the acquisition of the desirable image quality, and accordingly, a large number of correction algorisms based on the rules of thumb are still employed forcibly. The contents and problems of the gradation compression processing applied to an image captured under the backlight condition or the strobe lighting condition for a near subject will be detailed in the following.

A principal object of the gradation compression processing is to reproduce an image of human face with an appropriate brightness. Accordingly, it has been requested to propose a method for appropriately reproducing the brightness of the human face, in which an accuracy of extracting an image area of the human face is compensated for by the scene distinguishing operation for distinguishing the backlight condition and the strobe lighting condition from each other, and as a result, the brightness of the human face can be reproduced more appropriately than ever.

For instance, to improve the accuracy of extracting an image area of the human face, a method for distinguishing a position of the light source located at the time of the image-capturing operation and the kind of the light source is set forth in Patent Document 1. Further, as the methods for extracting an image area of the human face, Patent Document 1 also cites a method for employing a two-dimensional histogram of hue and chroma saturation, set forth in Patent Document 2, a pattern matching method and a pattern retrieving method set forth in Patent Document 3, Patent Document 4 and Patent Document 5. Still further, as a method for eliminating a background area other than the human face, Patent Document 1 also cites a method for distinguishing it by employing a ratio of straight line portion, a linear symmetry, a contact ratio of outer edge of the image screen, a density contrast and a pattern and period of the density variation, set forth in Patent Document 3 and Patent Document 4. Still further, a method of employing one-dimensional histogram of the brightness for distinguishing the backlight condition and the strobe lighting condition from each other, is also set forth. This method premises such the rules of thumbs that the face area is dark and the background area is bright in the case of the backlight condition, while the face area is bright and the background area is dark in the case of the strobe lighting condition. In other words, the brightness eccentricity amount is calculated in respect to the face area extracted as a candidate area of the human face, and then, when the brightness eccentricity amount exhibits a large value, the scene distinguishing operation is conducted for distinguishing the backlight condition and the strobe lighting condition from each other, so as to adjust an allowance width of the extracting condition of the face area only when the result of the scene distinguishing operation conforms with the rules of thumbs mentioned in the above.

Even for an image of human face other than such highlighted images captured under the backlight condition or the strobe lighting condition to an extent that it is doubtful whether or not the images represent human faces, there has been a natural demand for changing the brightness of the face area, positioned as a main subject in the total image, to an appropriate brightness, and for this purpose, many proposals have been issued. For instance, a method of grouping the pixels, which are located adjacent to each other and have hues and chroma saturations being approximate relative to each other, to calculate a printing density from the simple average of each group and a number of pixels included in each group, is set forth in Patent Document 6. The purpose of this method is to suppress influences of subjects other than the main subject by adjusting the total density of the printed image, and therefore, the gradation compression processing and a weighting operation limited to the face area are excluded from this method.

[Patent Document 1]
Tokkai 2000-148980

[Patent Document 2]
Tokkaihei 6-67320

[Patent Document 3]
Tokkaihei 8-122944

[Patent Document 4]
Tokkaihei 8-184925

[Patent Document 5]
Tokkaihei 9-138471

[Patent Document 6]
Tokkaihei 9-191474

Patent Documents 1-6 are included in Japanese Non-Examined Patent Publications.

The gradation compression processing includes the steps of: calculating an average brightness of a specific area over which a specific subject such as a human face is distributed; defining a gradation conversion curve for converting the average brightness calculated in the calculating step to a desired value; and applying the gradation conversion curve defined in the defining step to the image data. Although it is desirable that a weighting ratio of brightness for the face area (a contribution ratio of the face area) is adjusted according to the scene to be photographed when calculating the average brightness, the scope of adjustment for the contribution ratio would be considerably limited in the case of such extent that the backlight condition and the strobe lighting condition are distinguished from each other.

Further, the subject for the gradation compression processing at the time of the image-capturing operation for the near subject-image under the backlight condition or the strobe lighting condition is how to compensate for the extracting accuracy of the face area, and as a result, how to improve the accuracy of the brightness correction for the face area. As aforementioned, the method of employing the one-dimensional histogram would exhibit an effect to some extent, when placing the accuracy compensation at its major point. It must be said, however, that the above-mentioned method is insufficient for the demand of grasping the state of scene to be photographed more accurately, instead of whether or not it conforms to a clear definition such as the backlight condition or the strobe lighting condition. Still further, it is needless to say that, with respect to the gradation compression processing itself at the time of the image-capturing operation for the near subject-image under the backlight condition or the strobe lighting condition, the correction corresponding to a degree of the backlight or the strobe lighting should be required.

### SUMMARY OF THE INVENTION

To overcome the abovementioned drawbacks in conventional image-processing methods and apparatuses, it is an object of the present invention to provide image-processing method and apparatus, and an image-recording apparatus, which makes it possible to apply a highly-accurate scene distinguishing operation.

Accordingly, to overcome the cited shortcomings, the abovementioned object of the present invention can be attained by image-processing method and apparatus, and image-recording apparatus described as follow.

An image processing method of obtaining captured image data of pixels corresponding to one image plane and outputting image data optimized for viewing on an outputting medium, comprises:
(1) a color specifying process of acquiring a hue value and a brightness value for every pixel of the captured image data;
(2) a brightness value distributing process of dividing a brightness region into plural brightness regions by a predetermined brightness value and distributing the pixels of the captured image data in accordance with the brightness value of each pixel into one of the plural brightness regions;
(3) a color specification value distributing process of dividing a two dimensional color specification region into plural color specification regions by predetermined hue and brightness values and distributing the pixels of the captured image data in accordance with the hue and brightness values of each pixel into one of the plural color specification regions;
(4) a brightness region occupation ratio calculating process of calculating a brightness region occupation ratio representing a occupation ratio of the distributed pixels of each brightness region to all pixels of the one image plane;
(5) a color specification region occupation ratio calculating process of calculating a color specification region occupation ratio representing a occupation ratio of the distributed pixels of each color specification region to all pixels of the one image plane; and
(6) a photographing scene estimating process of estimating a photographing scene of the captured image data on the basis of the calculated brightness region occupation ratio and the calculated color specification region occupation ratio.

An image processing apparatus of obtaining captured image data of pixels corresponding to one image plane and outputting image data optimized for viewing on an outputting medium, comprises:
(1) a color specifying section for acquiring a hue value and a brightness value for every pixel of the captured image data;
(2) a brightness value distributing section for dividing a brightness region into plural brightness regions by a predetermined brightness value and distributing the pixels of the captured image data in accordance with the brightness value of each pixel into one of the plural brightness regions;
(3) a color specification value distributing section for dividing a two dimensional color specification region into plural color specification regions by predetermined hue and brightness values and distributing the pixels of the captured image data in accordance with the hue and brightness values of each pixel into one of the plural color specification regions;
(4) a brightness region occupation ratio calculating section for calculating a brightness region occupation ratio representing a occupation ratio of the distributed pixels of each brightness region to all pixels of the one image plane;
(5) a color specification region occupation ratio calculating section for calculating a color specification region occupation ratio representing a occupation ratio of the distributed pixels of each color specification region to all pixels of the one image plane; and
(6) a photographing scene estimating section for estimating a photographing scene of the captured image data on the basis of the calculated brightness region occupation ratio and the calculated color specification region occupation ratio.

### BRIEF DESCRIPTION OF THE DRAWINGS

Other objects and advantages of the present invention will become apparent upon reading the following detailed description and upon reference to the drawings in which:

FIG. 1 shows a perspective view of the outlook structure of image-recording apparatus 1 embodied in the present invention;

FIG. 2 shows a block diagram of an internal configuration of image-recording apparatus 1 shown in FIG. 1;

FIG. 3 shows a block diagram of a functional configuration of image processing section 70 shown in FIG. 2;

FIG. 4 shows a flowchart of the photographed scene estimation processing “A” conducted by image adjustment processing section 701 shown in FIG. 3;

FIG. 5 shows an example of a two-dimensional histogram;

FIG. 6 shows a flowchart of a gradation conversion processing performed by image adjustment processing section 701 shown in FIG. 3;

FIG. 7 shows an example of a gradation conversion curve;

FIG. 8 shows a flowchart of a photographed scene estimation processing “B” conducted by image adjustment processing section 701 shown in FIG. 3;

FIG. 9 shows an example of a two-dimensional histogram; and

FIG. 10 shows a flowchart of a photographed scene estimation processing “C” conducted by image adjustment processing section 701 shown in FIG. 3.

### DETAILED DESCRIPTION OF THE PREFERRED EMBODIMENT

Further, to overcome the abovementioned problems, other image-processing method and apparatus, and image-recording apparatus, embodied in the present invention, will be described as follow:
(Item 1) An image-processing method, characterized in that,
   in the image-processing method for inputting captured image data and outputting image data optimized for viewing an output image on an outputting medium, the image-processing method includes the processing steps of:
   acquiring a hue value and a brightness value for every pixel included in the captured image data;
   dividing the captured image data into predetermined brightness areas;
   dividing the captured image data into areas each of which consists of a combination of predetermined hue and brightness;
   calculating occupation ratios each of which indicates a ratio of the pixels for every brightness area divided in the above to an overall image area of the captured image data, respectively;
   calculating occupation ratios each of which indicates a ratio of the pixels for every divided area consisting of the combination of predetermined hue and brightness to the overall image area of the captured image data, respectively; and
   estimating a photographed scene, based on the calculated occupation ratio for every brightness area and the occupation ratio for every divided area consisting of the combination of predetermined hue and brightness.
(Item 2) An image-processing method, characterized in that,
   in the image-processing method for inputting captured image data and outputting image data optimized for viewing an output image on an outputting medium, the image-processing method includes the processing steps of:
   acquiring a hue value, a brightness value and saturation value for every pixel included in the captured image data;
   dividing the captured image data into predetermined brightness areas;
   dividing the captured image data into predetermined hue areas;
   dividing the captured image data into areas each of which consists of a combination of predetermined hue and saturation;
   calculating occupation ratios each of which indicates a ratio of the pixels for every brightness area divide in the above to an overall image area of the captured image data, respectively;
   calculating occupation ratios each of which indicates a ratio of the pixels for every hue area divided in the above to an overall image area of the captured image data, respectively;
   calculating an average brightness value for every divided area consisting of the combination of predetermined hue and saturation; and
   estimating a photographed scene, based on the calculated occupation ratio for every brightness area, the calculated occupation ratio for every hue area and the average brightness value.
(Item 3) An image-processing method, characterized in that,
   in the image-processing method for inputting captured image data and outputting image data optimized for viewing an output image on an outputting medium, the image-processing method includes the processing steps of:
   acquiring a hue value, a brightness value and saturation value for every pixel included in the captured image data;
   dividing the captured image data into predetermined brightness areas;
   dividing the captured image data into areas each of which consists of a combination of predetermined hue, saturation and brightness;
   calculating occupation ratios each of which indicates a ratio of the pixels for every brightness area divided in the above to an overall image area of the captured image data, respectively;
   calculating occupation ratios each of which indicates a ratio of the pixels for every divided area consisting of the combination of predetermined hue, saturation and brightness to the overall image area of the captured image data, respectively; and
   estimating a photographed scene, based on the calculated occupation ratio for every brightness area and the occupation ratio for every divided area consisting of the combination of predetermined hue, saturation and brightness.
(Item 4) An image-processing method, characterized in that,
   in the image-processing method for inputting captured image data and outputting image data optimized for viewing an output image on an outputting medium, the image-processing method includes the processing steps of:
   acquiring a hue value, a brightness value and saturation value for every pixel included in the captured image data;
   dividing the captured image data into predetermined brightness areas;
   dividing the captured image data into predetermined hue areas;
   dividing the captured image data into areas each of which consists of a combination of predetermined hue, saturation and brightness;
   dividing the captured image data into areas each of which consists of a combination of predetermined hue and saturation;
   calculating occupation ratios each of which indicates a ratio of the pixels for every brightness area divide in the above to an overall image area of the captured image data, respectively;
   calculating occupation ratios each of which indicates a ratio of the pixels for every hue area divided in the above to an overall image area of the captured image data, respectively;
   calculating occupation ratios each of which indicates a ratio of the pixels for every divided area consisting of the combination of predetermined hue, saturation and brightness to the overall image area of the captured image data, respectively;
   calculating an average brightness value for every divided area consisting of the combination of predetermined hue and saturation to the overall image area of the captured image data, respectively; and
   estimating a photographed scene, based on the calculated occupation ratio for every brightness area, the calculated occupation ratio for every hue area, the calculated occupation ratio for every divided area consisting of the combination of predetermined hue, saturation and brightness and the average brightness value.
(Item 5) An image-processing method, characterized in that,
   in the image-processing method for inputting captured image data and outputting image data optimized for viewing an output image on an outputting medium, the image-processing method includes the processing steps of:
   acquiring a hue value and a brightness value for every pixel included in the captured image data;
   dividing the captured image data into predetermined brightness areas;
   dividing the captured image data into areas each of which consists of a combination of predetermined hue and brightness;
   calculating occupation ratios each of which indicates a ratio of the pixels for every brightness area divided in the above to an overall image area of the captured image data, respectively;
   calculating occupation ratios each of which indicates a ratio of the pixels for every divided area consisting of the combination of predetermined hue and brightness to the overall image area of the captured image data, respectively;
   estimating a photographed scene, based on the calculated occupation ratio for every brightness area and the occupation ratio for every divided area consisting of the combination of predetermined hue and brightness;
   extracting a face area of the captured image data;
   determining a contribution ratio of the face area for a gradation conversion processing, based on the photographed scene estimated in the above; and
   applying the gradation conversion processing to the captured image data, based on the contribution ratio determined in the above.
(Item 6) An image-processing method, characterized in that,
   in the image-processing method for inputting captured image data and outputting image data optimized for viewing an output image on an outputting medium, the image-processing method includes the processing steps of:
   acquiring a hue value, a brightness value and saturation value for every pixel included in the captured image data;
   dividing the captured image data into predetermined brightness areas;
   dividing the captured image data into predetermined hue areas;
   dividing the captured image data into areas each of which consists of a combination of predetermined hue and saturation;
   calculating occupation ratios each of which indicates a ratio of the pixels for every brightness area divide in the above to an overall image area of the captured image data, respectively;
   calculating occupation ratios each of which indicates a ratio of the pixels for every hue area divided in the above to an overall image area of the captured image data, respectively;
   calculating an average brightness value for every divided area consisting of the combination of predetermined hue and saturation to the overall image area of the captured image data, respectively;
   estimating a photographed scene, based on the calculated occupation ratio for every brightness area, the calculated occupation ratio for every hue area and the average brightness value;
   extracting a face area of the captured image data;
   determining a contribution ratio of the face area for a gradation conversion processing, based on the photographed scene estimated in the above; and
   applying the gradation conversion processing to the captured image data, based on the contribution ratio determined in the above.
(Item 7) An image-processing method, characterized in that,
   in the image-processing method for inputting captured image data and outputting image data optimized for viewing an output image on an outputting medium, the image-processing method includes the processing steps of:
   acquiring a hue value, a brightness value and saturation value for every pixel included in the captured image data;
   dividing the captured image data into predetermined brightness areas;
   dividing the captured image data into areas each of which consists of a combination of predetermined hue, saturation and brightness;
   calculating occupation ratios each of which indicates a ratio of the pixels for every brightness area divided in the above to an overall image area of the captured image data, respectively;
   calculating occupation ratios each of which indicates a ratio of the pixels for every divided area consisting of the combination of predetermined hue, saturation and brightness to the overall image area of the captured image data, respectively;
   estimating a photographed scene, based on the calculated occupation ratio for every brightness area and the occupation ratio for every divided area consisting of the combination of predetermined hue, saturation and brightness;
   extracting a face area of the captured image data;
   determining a contribution ratio of the face area for a gradation conversion processing, based on the photographed scene estimated in the above; and
   applying the gradation conversion processing to the captured image data, based on the contribution ratio determined in the above.
(Item 8) An image-processing method, characterized in that,
   in the image-processing method for inputting captured image data and outputting image data optimized for viewing an output image on an outputting medium, the image-processing method includes the processing steps of:
   acquiring a hue value, a brightness value and saturation value for every pixel included in the captured image data;
   dividing the captured image data into predetermined brightness areas;
   dividing the captured image data into predetermined hue areas;
   dividing the captured image data into areas each of which consists of a combination of predetermined hue, saturation and brightness;
   dividing the captured image data into areas each of which consists of a combination of predetermined hue and saturation;
   calculating occupation ratios each of which indicates a ratio of the pixels for every brightness area divide in the above to an overall image area of the captured image data, respectively;
   calculating occupation ratios each of which indicates a ratio of the pixels for every hue area divided in the above to an overall image area of the captured image data, respectively;
   calculating occupation ratios each of which indicates a ratio of the pixels for every divided area consisting of the combination of predetermined hue, saturation and brightness to the overall image area of the captured image data, respectively;
   calculating an average brightness value for every divided area consisting of the combination of predetermined hue and saturation to the overall image area of the captured image data, respectively;
   estimating a photographed scene, based on the calculated occupation ratio for every brightness area, the calculated occupation ratio for every hue area, the calculated occupation ratio for every divided area consisting of the combination of predetermined hue, saturation and brightness and the average brightness value;
   extracting a face area of the captured image data;
   determining a contribution ratio of the face area for a gradation conversion processing, based on the photographed scene estimated in the above; and
   applying the gradation conversion processing to the captured image data, based on the contribution ratio determined in the above.
(Item 9) The image-processing method, described in item 1 or 5, characterized in that,
   in the processing step of dividing the captured image data into predetermined brightness areas, the captured image data are divided into a shadow area having a brightness value in a range of 0-84, an intermediate area having a brightness value in a range of 85-169 and a highlighted area having a brightness value in a range of 170-255, each as a value defined by the HSV color specification system, and
   in the processing step of dividing the captured image data into the areas each of which consists of the combination of predetermined hue and brightness, the captured image data are divided into a flesh-color shadow area having a hue value in a range of 0-69 and a brightness value in a range of 0-84, a flesh-color intermediate area having a hue value in a range of 0-69 and a brightness value in a range of 85-169 and a flesh-color highlighted area having a hue value in a range of 0-69 and a brightness value in a range of 170-255, each as a value defined by the HSV color specification system.
(Item 10) The image-processing method, described in item 2 or 6, characterized in that,
   in the processing step of dividing the captured image data into predetermined brightness areas, the captured image data are divided into a shadow area having a brightness value in a range of 0-84, an intermediate area having a brightness value in a range of 85-169 and a highlighted area having a brightness value in a range of 170-255, each as a value defined by the HSV color specification system, and
   in the processing step of dividing the captured image data into predetermined hue areas, the captured image data are divided into a flesh-color hue area having a hue value in a range of 0-69, a green hue area having a hue value in a range of 70-184, a sky-blue hue area having a hue value in a range of 185-224 and a red hue area having a hue value in a range of 225-360, each as a value defined by the HSV color specification system, and
   in the processing step of dividing the captured image data into the areas each of which consists of the combination of predetermined hue and brightness, the captured image data are divided into at least a flesh-color area having a hue value in a range of 0-69 and a saturation value in a range of 0-128, each as a value defined by the HSV color specification system.
(Item 11) The image-processing method, described in item 3 or 7, characterized in that,
   in the processing step of dividing the captured image data into predetermined brightness areas, the captured image data are divided into a shadow area having a brightness value in a range of 0-84, an intermediate area having a brightness value in a range of 85-169 and a highlighted area having a brightness value in a range of 170-255, each as a value defined by the HSV color specification system, and
   in the processing step of dividing the captured image data into the areas each of which consists of the combination of predetermined hue, saturation and brightness, the captured image data are divided into a flesh-color shadow area having a hue value in a range of 0-69, a saturation value in a range of 0-128 and a brightness value in a range of 0-84, a flesh-color intermediate area having a hue value in a range of 0-69, a saturation value in a range of 0-128 and a brightness value in a range of 85-169, and a flesh-color highlighted area having a hue value in a range of 0-69, a saturation value in a range of 0-128 and a brightness value in a range of 170-255, each as a value defined by the HSV color specification system.
(Item 12) The image-processing method, described in item 4 or 8, characterized in that,
   in the processing step of dividing the captured image data into predetermined brightness areas, the captured image data are divided into a shadow area having a brightness value in a range of 0-84, an intermediate area having a brightness value in a range of 85-169 and a highlighted area having a brightness value in a range of 170-255, each as a value defined by the HSV color specification system, and
   in the processing step of dividing the captured image data into predetermined hue areas, the captured image data are divided into a flesh-color hue area having a hue value in a range of 0-69, a green hue area having a hue value in a range of 70-184, a sky-blue hue area having a hue value in a range of 185-224 and a red hue area having a hue value in a range of 225-360, each as a value defined by the HSV color specification system, and
   in the processing step of dividing the captured image data into the areas each of which consists of the combination of predetermined hue, saturation and brightness, the captured image data are divided into a flesh-color shadow area having a hue value in a range of 0-69, a saturation value in a range of 0-128 and a brightness value in a range of 0-84, a flesh-color intermediate area having a hue value in a range of 0-69, a saturation value in a range of 0-128 and a brightness value in a range of 85-169, and a flesh-color highlighted area having a hue value in a range of 0-69, a saturation value in a range of 0-128 and a brightness value in a range of 170-255, each as a value defined by the HSV color specification system, and
   in the processing step of dividing the captured image data into the areas each of which consists of the combination of predetermined hue and brightness, the captured image data are divided into at least a flesh-color area having a hue value in a range of 0-69 and a saturation value in a range of 0-128, each as a value defined by the HSV color specification system.
(Item 13) The image-processing method, described in any one of items 1, 5 and 9, characterized in that,
   the image-processing method further includes the processing step of creating a two-dimensional histogram of the hue value and the brightness value acquired in the previous step, and
   based on the two-dimensional histogram created in the above, the captured image data is divided into the predetermined brightness areas and the areas each of which consists of the combination of predetermined brightness area and the predetermined hue area, respectively.
(Item 14) The image-processing method, described in any one of items 2, 6 and 10, characterized in that,
   the image-processing method further includes the processing step of creating a three-dimensional histogram of the hue value, the saturation value and the brightness value acquired in the previous step, and
   based on the three-dimensional histogram created in the above, the captured image data is divided into the predetermined brightness areas, the predetermined hue areas, and the areas each of which consists of the combination of predetermined hue and saturation, respectively.
(Item 15) The image-processing method, described in any one of items 3, 7 and 11, characterized in that,
   the image-processing method further includes the processing step of creating a three-dimensional histogram of the hue value, the saturation value and the brightness value acquired in the previous step, and
   based on the three-dimensional histogram created in the above, the captured image data is divided into the predetermined brightness areas and the areas each of which consists of the combination of predetermined hue, saturation and brightness, respectively.
(Item 16) The image-processing method, described in any one of items 4, 8 and 12, characterized in that,
   the image-processing method further includes the processing step of creating a three-dimensional histogram of the hue value, the saturation value and the brightness value acquired in the previous step, and
   based on the three-dimensional histogram created in the above, the captured image data is divided into the predetermined brightness areas, the predetermined hue areas, the areas each of which consists of the combination of predetermined hue, saturation and brightness, and the areas each of which consists of the combination of predetermined hue and saturation, respectively.
(Item 17) The image-processing method, described in any one of items 5-16, characterized in that,
   in the processing step of extracting the face area, an area consisting of the combination of predetermined hue and saturation in the captured image data is extracted as the face area.
(Item 18) The image-processing method, described in item 17, characterized in that,
   in the processing step of extracting the face area, a two-dimensional histogram of the hue value and the saturation value in the captured image data is created, and
   based on the two-dimensional histogram created in the above, the area consisting of the combination of predetermined hue and saturation is extracted as the face area.
(Item 19) The image-processing method, described in item 17 or 18, characterized in that,
   the area consisting of the combination of predetermined hue and saturation is such an area having a hue value in a range of 0-50 and a brightness value in a range of 10-120, each as a value defined by the HSV color specification system in the captured image data.
(Item 20) The image-processing method, described in any one of items 5-19, characterized in that,
   in the processing step of applying the gradation conversion processing to the captured image data, based on the contribution ratio determined in the above, the gradation conversion processing is applied to the captured image data by conducting the steps of: calculating an average brightness input value, based on the contribution ratio of the face area; adjusting a gradation conversion curve either by creating a new gradation conversion curve for converting the average brightness input value to a target conversion value of average brightness value established in advance or by selecting a suitable one out of a plurality of gradation conversion curves established in advance; and employing the gradation conversion curve adjusted in the above step.
(Item 21) The image-processing method, described in any one of items 1-20, characterized in that,
   the captured image data are scene-referred image data.
(Item 22) The image-processing method, described in any one of items 1-21, characterized in that,
   the image data optimized for viewing the output image on the outputting medium are output-referred image data.
(Item 23) An image-processing apparatus, characterized in that,
   in the image-processing apparatus for inputting captured image data and outputting image data optimized for viewing an output image on an outputting medium, the image-processing apparatus is provided with:
   a data acquiring means for acquiring a hue value and a brightness value for every pixel included in the captured image data;
   a brightness area dividing means for dividing the captured image data into predetermined brightness areas;
   an HV dividing means for dividing the captured image data into areas each of which consists of a combination of predetermined hue and brightness;
   an brightness-area occupation ratio calculating means for calculating occupation ratios each of which indicates a ratio of the pixels for every brightness area divided in the above to an overall image area of the captured image data, respectively;
   an HV occupation ratio calculating means for calculating occupation ratios each of which indicates a ratio of the pixels for every divided area consisting of the combination of predetermined hue and brightness to the overall image area of the captured image data, respectively; and
   a photographed scene estimating means for estimating a photographed scene, based on the calculated occupation ratio for every brightness area and the occupation ratio for every divided area consisting of the combination of predetermined hue and brightness.
(Item 24) An image-processing apparatus, characterized in that,
   in the image-processing apparatus for inputting captured image data and outputting image data optimized for viewing an output image on an outputting medium, the image-processing apparatus is provided with:
   a data acquiring means for acquiring a hue value, a brightness value and saturation value for every pixel included in the captured image data;
   a brightness area dividing means for dividing the captured image data into predetermined brightness areas;
   a hue area dividing means for dividing the captured image data into predetermined hue areas;
   an HS dividing means for dividing the captured image data into areas each of which consists of a combination of predetermined hue and saturation;
   a brightness-area occupation ratio calculating means for calculating occupation ratios each of which indicates a ratio of the pixels for every brightness area divide in the above to an overall image area of the captured image data, respectively;
   a hue-area occupation ratio calculating means for calculating occupation ratios each of which indicates a ratio of the pixels for every hue area divided in the above to an overall image area of the captured image data, respectively;
   an average brightness-value calculating means for calculating an average brightness value for every divided area consisting of the combination of predetermined hue and saturation; and
   a photographed scene estimating means for estimating a photographed scene, based on the calculated occupation ratio for every brightness area, the calculated occupation ratio for every hue area and the average brightness value.
(Item 25) An image-processing apparatus, characterized in that,
   in the image-processing apparatus for inputting captured image data and outputting image data optimized for viewing an output image on an outputting medium, the image-processing apparatus is provided with:
   a data acquiring means for acquiring a hue value, a brightness value and saturation value for every pixel included in the captured image data;
   a brightness area dividing means for dividing the captured image data into predetermined brightness areas;
   an HSV dividing means for dividing the captured image data into areas each of which consists of a combination of predetermined hue, saturation and brightness;
   a brightness-area occupation ratio calculating means for calculating occupation ratios each of which indicates a ratio of the pixels for every brightness area divided in the above to an overall image area of the captured image data, respectively;
   an HSV occupation ratio calculating means for calculating occupation ratios each of which indicates a ratio of the pixels for every divided area consisting of the combination of predetermined hue, saturation and brightness to the overall image area of the captured image data, respectively; and
   a photographed scene estimating means for estimating a photographed scene, based on the calculated occupation ratio for every brightness area and the occupation ratio for every divided area consisting of the combination of predetermined hue, saturation and brightness.
(Item 26) An image-processing apparatus, characterized in that,
   in the image-processing apparatus for inputting captured image data and outputting image data optimized for viewing an output image on an outputting medium, the image-processing apparatus is provided with:
   a data acquiring means for acquiring a hue value, a brightness value and saturation value for every pixel included in the captured image data;
   a brightness area dividing means for dividing the captured image data into predetermined brightness areas;
   a hue area dividing means for dividing the captured image data into predetermined hue areas;
   an HSV dividing means for dividing the captured image data into areas each of which consists of a combination of predetermined hue, saturation and brightness;
   an HS dividing means for dividing the captured image data into areas each of which consists of a combination of predetermined hue and saturation;
   a brightness-area occupation ratio calculating means for calculating occupation ratios each of which indicates a ratio of the pixels for every brightness area divide in the above to an overall image area of the captured image data, respectively;
   a hue-area occupation ratio calculating means for calculating occupation ratios each of which indicates a ratio of the pixels for every hue area divided in the above to an overall image area of the captured image data, respectively;
   an HSV occupation ratio calculating means for calculating occupation ratios each of which indicates a ratio of the pixels for every divided area consisting of the combination of predetermined hue, saturation and brightness to the overall image area of the captured image data, respectively;
   an average brightness-value calculating means for calculating an average brightness value for every divided area consisting of the combination of predetermined hue and saturation to the overall image area of the captured image data, respectively; and
   a photographed scene estimating means for estimating a photographed scene, based on the calculated occupation ratio for every brightness area, the calculated occupation ratio for every hue area, the calculated occupation ratio for every divided area consisting of the combination of predetermined hue, saturation and brightness and the average brightness value.
(Item 27) An image-processing apparatus, characterized in that,
   in the image-processing apparatus for inputting captured image data and outputting image data optimized for viewing an output image on an outputting medium, the image-processing apparatus is provided with:
   a data acquiring means for acquiring a hue value and a brightness value for every pixel included in the captured image data;
   a brightness area dividing means for dividing the captured image data into predetermined brightness areas;
   an HV dividing means for dividing the captured image data into areas each of which consists of a combination of predetermined hue and brightness;
   a brightness area occupation ratio calculating means for calculating occupation ratios each of which indicates a ratio of the pixels for every brightness area divided in the above to an overall image area of the captured image data, respectively;
   an HV occupation ratio calculating means for calculating occupation ratios each of which indicates a ratio of the pixels for every divided area consisting of the combination of predetermined hue and brightness to the overall image area of the captured image data, respectively;
   a photographed scene estimating means for estimating a photographed scene, based on the calculated occupation ratio for every brightness area and the occupation ratio for every divided area consisting of the combination of predetermined hue and brightness;
   a face area extracting means for extracting a face area of the captured image data;
   a contribution ratio determining means for determining a contribution ratio of the face area for a gradation conversion processing, based on the photographed scene estimated in the above; and
   a gradation conversion processing means for applying the gradation conversion processing to the captured image data, based on the contribution ratio determined in the above.
(Item 28) An image-processing apparatus, characterized in that,
   in the image-processing apparatus for inputting captured image data and outputting image data optimized for viewing an output image on an outputting medium, the image-processing apparatus is provided with:
   a data acquiring means for acquiring a hue value, a brightness value and saturation value for every pixel included in the captured image data;
   a brightness area dividing means for dividing the captured image data into predetermined brightness areas;
   a hue area dividing means for dividing the captured image data into predetermined hue areas;
   an HS dividing means for dividing the captured image data into areas each of which consists of a combination of predetermined hue and saturation;
   a brightness-area occupation ratio calculating means for calculating occupation ratios each of which indicates a ratio of the pixels for every brightness area divide in the above to an overall image area of the captured image data, respectively;
   a hue-area occupation ratio calculating means for calculating occupation ratios each of which indicates a ratio of the pixels for every hue area divided in the above to an overall image area of the captured image data, respectively;
   an average brightness value calculating means for calculating an average brightness value for every divided area consisting of the combination of predetermined hue and saturation to the overall image area of the captured image data, respectively;
   a photographed scene estimating means for estimating a photographed scene, based on the calculated occupation ratio for every brightness area, the calculated occupation ratio for every hue area and the average brightness value;
   a face area extracting means for extracting a face area of the captured image data;
   a contribution ratio determining means for determining a contribution ratio of the face area for a gradation conversion processing, based on the photographed scene estimated in the above; and
   a gradation conversion processing means for applying the gradation conversion processing to the captured image data, based on the contribution ratio determined in the above.
(Item 29) An image-processing apparatus, characterized in that,
   in the image-processing apparatus for inputting captured image data and outputting image data optimized for viewing an output image on an outputting medium, the image-processing apparatus is provided with:
   a data acquiring means for acquiring a hue value, a brightness value and saturation value for every pixel included in the captured image data;
   a brightness area dividing means for dividing the captured image data into predetermined brightness areas;
   an HSV dividing means for dividing the captured image data into areas each of which consists of a combination of predetermined hue, saturation and brightness;
   a brightness-area occupation ratio calculating means for calculating occupation ratios each of which indicates a ratio of the pixels for every brightness area divided in the above to an overall image area of the captured image data, respectively;
   an HSV occupation ratio calculating means for calculating occupation ratios each of which indicates a ratio of the pixels for every divided area consisting of the combination of predetermined hue, saturation and brightness to the overall image area of the captured image data, respectively;
   a photographed scene estimating means for estimating a photographed scene, based on the calculated occupation ratio for every brightness area and the occupation ratio for every divided area consisting of the combination of predetermined hue, saturation and brightness;
   a face area extracting means for extracting a face area of the captured image data;
   a contribution ratio determining means for determining a contribution ratio of the face area for a gradation conversion processing, based on the photographed scene estimated in the above; and
   a gradation conversion processing means for applying the gradation conversion processing to the captured image data, based on the contribution ratio determined in the above.
(Item 30) An image-processing apparatus, characterized in that,
   in the image-processing apparatus for inputting captured image data and outputting image data optimized for viewing an output image on an outputting medium, the image-processing apparatus is provided with:
   a data acquiring means for acquiring a hue value, a brightness value and saturation value for every pixel included in the captured image data;
   a brightness area dividing means for dividing the captured image data into predetermined brightness areas;
   a hue area dividing means for dividing the captured image data into predetermined hue areas;
   an HSV dividing means for dividing the captured image data into areas each of which consists of a combination of predetermined hue, saturation and brightness;
   an HS dividing means for dividing the captured image data into areas each of which consists of a combination of predetermined hue and saturation;
   a brightness-area occupation ratio calculating means for calculating occupation ratios each of which indicates a ratio of the pixels for every brightness area divide in the above to an overall image area of the captured image data, respectively;
   a hue-area occupation ratio calculating means for calculating occupation ratios each of which indicates a ratio of the pixels for every hue area divided in the above to an overall image area of the captured image data, respectively;
   an HSV occupation ratio calculating means for calculating occupation ratios each of which indicates a ratio of the pixels for every divided area consisting of the combination of predetermined hue, saturation and brightness to the overall image area of the captured image data, respectively;
   an average brightness value calculating means for calculating an average brightness value for every divided area consisting of the combination of predetermined hue and saturation to the overall image area of the captured image data, respectively;
   a photographed scene estimating means for estimating a photographed scene, based on the calculated occupation ratio for every brightness area, the calculated occupation ratio for every hue area, the calculated occupation ratio for every divided area consisting of the combination of predetermined hue, saturation and brightness and the average brightness value;
   a face area extracting means for extracting a face area of the captured image data;
   a contribution ratio determining means for determining a contribution ratio of the face area for a gradation conversion processing, based on the photographed scene estimated in the above; and
   a gradation conversion processing means for applying the gradation conversion processing to the captured image data, based on the contribution ratio determined in the above.
(Item 31) The image-processing apparatus, described in item 23 or 27, characterized in that,
   the brightness area dividing means divides the captured image data into a shadow area having a brightness value in a range of 0-84, an intermediate area having a brightness value in a range of 85-169 and a highlighted area having a brightness value in a range of 170-255, each as a value defined by the HSV color specification system, and
   the HV dividing means divides the captured image data into a flesh-color shadow area having a hue value in a range of 0-69 and a brightness value in a range of 0-84, a flesh-color intermediate area having a hue value in a range of 0-69 and a brightness value in a range of 85-169 and a flesh-color highlighted area having a hue value in a range of 0-69 and a brightness value in a range of 170-255, each as a value defined by the HSV color specification system.
(Item 32) The image-processing apparatus, described in item 24 or 28, characterized in that,
   the brightness area dividing means divides the captured image data into a shadow area having a brightness value in a range of 0-84, an intermediate area having a brightness value in a range of 85-169 and a highlighted area having a brightness value in a range of 170-255, each as a value defined by the HSV color specification system, and
   the hue area dividing means divides the captured image data into a flesh-color hue area having a hue value in a range of 0-69, a green hue area having a hue value in a range of 70-184, a sky-blue hue area having a hue value in a range of 185-224 and a red hue area having a hue value in a range of 225-360, each as a value defined by the HSV color specification system, and
   the HS dividing means divides the captured image data into at least a flesh-color area having a hue value in a range of 0-69 and a saturation value in a range of 0-128, each as a value defined by the HSV color specification system.
(Item 33) The image-processing apparatus, described in item 25 or 29, characterized in that,
   the brightness area dividing means divides the captured image data into a shadow area having a brightness value in a range of 0-84, an intermediate area having a brightness value in a range of 85-169 and a highlighted area having a brightness value in a range of 170-255, each as a value defined by the HSV color specification system, and
   the HSV dividing means divides the captured image data into a flesh-color shadow area having a hue value in a range of 0-69, a saturation value in a range of 0-128 and a brightness value in a range of 0-84, a flesh-color intermediate area having a hue value in a range of 0-69, a saturation value in a range of 0-128 and a brightness value in a range of 85-169, and a flesh-color highlighted area having a hue value in a range of 0-69, a saturation value in a range of 0-128 and a brightness value in a range of 170-255, each as a value defined by the HSV color specification system.
(Item 34) The image-processing apparatus, described in item 26 or 30, characterized in that,
   the brightness area dividing means divides the captured image data into a shadow area having a brightness value in a range of 0-84, an intermediate area having a brightness value in a range of 85-169 and a highlighted area having a brightness value in a range of 170-255, each as a value defined by the HSV color specification system, and
   the hue area dividing means divides the captured image data into a flesh-color hue area having a hue value in a range of 0-69, a green hue area having a hue value in a range of 70-184, a sky-blue hue area having a hue value in a range of 185-224 and a red hue area having a hue value in a range of 225-360, each as a value defined by the HSV color specification system, and
   the HSV dividing means divides the captured image data into a flesh-color shadow area having a hue value in a range of 0-69, a saturation value in a range of 0-128 and a brightness value in a range of 0-84, a flesh-color intermediate area having a hue value in a range of 0-69, a saturation value in a range of 0-128 and a brightness value in a range of 85-169, and a flesh-color highlighted area having a hue value in a range of 0-69, a saturation value in a range of 0-128 and a brightness value in a range of 170-255, each as a value defined by the HSV color specification system, and
   the HS dividing means divides the captured image data into a flesh-color area having a hue value in a range of 0-69 and a saturation value in a range of 0-128, each as a value defined by the HSV color specification system.
(Item 35) The image-processing apparatus, described in any one of items 23, 27 and 31, characterized in that,
   the image-processing apparatus is further provided with a two-dimensional histogram creating means for creating a two-dimensional histogram of the hue value and the brightness value acquired previously, and
   based on the two-dimensional histogram created in the above, the brightness area dividing means divides the captured image data into the predetermined brightness areas and,
   based on the two-dimensional histogram created in the above, the HV dividing means divides the captured image data into the areas each of which consists of the combination of predetermined brightness area and the predetermined hue area.
(Item 36) The image-processing apparatus, described in any one of items 24, 28 and 32, characterized in that,
   the image-processing apparatus is further provided with a three-dimensional histogram creating means for creating a three-dimensional histogram of the hue value and the brightness value acquired previously, and
   based on the three-dimensional histogram created in the above, the brightness area dividing means divides the captured image data into the predetermined brightness areas and,
   based on the three-dimensional histogram created in the above, the hue area dividing means divides the captured image data into the predetermined hue areas and,
   based on the three-dimensional histogram created in the above, the HS dividing means divides the captured image data into the areas each of which consists of the combination of predetermined hue and saturation.
(Item 37) The image-processing apparatus, described in any one of items 25, 29 and 33, characterized in that,
   the image-processing apparatus is further provided with a three-dimensional histogram creating means for creating a three-dimensional histogram of the hue value and the brightness value acquired previously, and
   based on the three-dimensional histogram created in the above, the brightness area dividing means divides the captured image data into the predetermined brightness areas and,
   based on the three-dimensional histogram created in the above, the HSV dividing means divides the captured image data into the areas each of which consists of the combination of predetermined hue, saturation and brightness.
(Item 38) The image-processing apparatus, described in any one of items 26, 30 and 34, characterized in that,
   the image-processing apparatus is further provided with a three-dimensional histogram creating means for creating a three-dimensional histogram of the hue value and the brightness value acquired previously, and
   based on the three-dimensional histogram created in the above, the brightness area dividing means divides the captured image data into the predetermined brightness areas and,
   based on the three-dimensional histogram created in the above, the hue area dividing means divides the captured image data into the predetermined hue areas and,
   based on the three-dimensional histogram created in the above, the HSV dividing means divides the captured image data into the areas each of which consists of the combination of predetermined hue, saturation and brightness.
   based on the three-dimensional histogram created in the above, the HS dividing means divides the captured image data into the areas each of which consists of the combination of predetermined hue and saturation.
(Item 39) The image-processing apparatus, described in any one of items 27-38, characterized in that,
   the face area extracting means extracts an area consisting of the combination of predetermined hue and saturation in the captured image data as the face area.
(Item 40) The image-processing apparatus, described in item 39, characterized in that,
   the face area extracting means creates a two-dimensional histogram of the hue value and the saturation value in the captured image data, and extracts the area consisting of the combination of predetermined hue and saturation as the face area, based on the two-dimensional histogram created in the above.
(Item 41) The image-processing apparatus, described in item 39 or 40, characterized in that,
   the area consisting of the combination of predetermined hue and saturation, to be extracted as the face area, is such an area having a hue value in a range of 0-50 and a brightness value in a range of 10-120, each as a value defined by the HSV color specification system in the captured image data.
(Item 42) The image-processing apparatus, described in any one of items 27-41, characterized in that,
   the gradation conversion processing means applies the gradation conversion processing to the captured image data by conducting the steps of: calculating an average brightness input value, based on the contribution ratio of the face area; adjusting a gradation conversion curve either by creating a new gradation conversion curve for converting the average brightness input value to a target conversion value of average brightness value established in advance or by selecting a suitable one out of a plurality of gradation conversion curves established in advance; and employing the gradation conversion curve adjusted in the above step.
(Item 43) The image-processing apparatus, described in any one of items 23-42, characterized in that,
   the captured image data are scene-referred image data.
(Item 44) The image-processing apparatus, described in any one of items 23-43, characterized in that,
   the image data optimized for viewing the output image on the outputting medium are output-referred image data.
(Item 45) An image-recording apparatus, characterized in that,
   in the image-recording apparatus for inputting captured image data to generate image data optimized for viewing an output image on an outputting medium and for forming the output image based on the image data on the outputting medium, the image-recording apparatus is provided with:
   a data acquiring means for acquiring a hue value and a brightness value for every pixel included in the captured image data;
   a brightness area dividing means for dividing the captured image data into predetermined brightness areas;
   an HV dividing means for dividing the captured image data into areas each of which consists of a combination of predetermined hue and brightness;
   an brightness-area occupation ratio calculating means for calculating occupation ratios each of which indicates a ratio of the pixels for every brightness area divided in the above to an overall image area of the captured image data, respectively;
   an HV occupation ratio calculating means for calculating occupation ratios each of which indicates a ratio of the pixels for every divided area consisting of the combination of predetermined hue and brightness to the overall image area of the captured image data, respectively; and
   a photographed scene estimating means for estimating a photographed scene, based on the calculated occupation ratio for every brightness area and the occupation ratio for every divided area consisting of the combination of predetermined hue and brightness.
(Item 46) An image-recording apparatus, characterized in that,
   in the image-recording apparatus for inputting captured image data to generate image data optimized for viewing an output image on an outputting medium and for forming the output image based on the image data on the outputting medium, the image-recording apparatus is provided with:
   a data acquiring means for acquiring a hue value, a brightness value and saturation value for every pixel included in the captured image data;
   a brightness area dividing means for dividing the captured image data into predetermined brightness areas;
   a hue area dividing means for dividing the captured image data into predetermined hue areas;
   an HS dividing means for dividing the captured image data into areas each of which consists of a combination of predetermined hue and saturation;
   a brightness-area occupation ratio calculating means for calculating occupation ratios each of which indicates a ratio of the pixels for every brightness area divide in the above to an overall image area of the captured image data, respectively;
   a hue-area occupation ratio calculating means for calculating occupation ratios each of which indicates a ratio of the pixels for every hue area divided in the above to an overall image area of the captured image data, respectively;
   an average brightness-value calculating means for calculating an average brightness value for every divided area consisting of the combination of predetermined hue and saturation; and
   a photographed scene estimating means for estimating a photographed scene, based on the calculated occupation ratio for every brightness area, the calculated occupation ratio for every hue area and the average brightness value.
(Item 47) An image-recording apparatus, characterized in that,
   in the image-recording apparatus for inputting captured image data to generate image data optimized for viewing an output image on an outputting medium and for forming the output image based on the image data on the outputting medium, the image-recording apparatus is provided with:
   a data acquiring means for acquiring a hue value, a brightness value and saturation value for every pixel included in the captured image data;
   a brightness area dividing means for dividing the captured image data into predetermined brightness areas;
   an HSV dividing means for dividing the captured image data into areas each of which consists of a combination of predetermined hue, saturation and brightness;
   a brightness-area occupation ratio calculating means for calculating occupation ratios each of which indicates a ratio of the pixels for every brightness area divided in the above to an overall image area of the captured image data, respectively;
   an HSV occupation ratio calculating means for calculating occupation ratios each of which indicates a ratio of the pixels for every divided area consisting of the combination of predetermined hue, saturation and brightness to the overall image area of the captured image data, respectively; and
   a photographed scene estimating means for estimating a photographed scene, based on the calculated occupation ratio for every brightness area and the occupation ratio for every divided area consisting of the combination of predetermined hue, saturation and brightness.
(Item 48) An image-recording apparatus, characterized in that,
   in the image-recording apparatus for inputting captured image data to generate image data optimized for viewing an output image on an outputting medium and for forming the output image based on the image data on the outputting medium, the image-recording apparatus is provided with:
   a data acquiring means for acquiring a hue value, a brightness value and saturation value for every pixel included in the captured image data;
   a brightness area dividing means for dividing the captured image data into predetermined brightness areas;
   a hue area dividing means for dividing the captured image data into predetermined hue areas;
   an HSV dividing means for dividing the captured image data into areas each of which consists of a combination of predetermined hue, saturation and brightness;
   an HS dividing means for dividing the captured image data into areas each of which consists of a combination of predetermined hue and saturation;
   a brightness-area occupation ratio calculating means for calculating occupation ratios each of which indicates a ratio of the pixels for every brightness area divide in the above to an overall image area of the captured image data, respectively;
   a hue-area occupation ratio calculating means for calculating occupation ratios each of which indicates a ratio of the pixels for every hue area divided in the above to an overall image area of the captured image data, respectively;
   an HSV occupation ratio calculating means for calculating occupation ratios each of which indicates a ratio of the pixels for every divided area consisting of the combination of predetermined hue, saturation and brightness to the overall image area of the captured image data, respectively;
   an average brightness-value calculating means for calculating an average brightness value for every divided area consisting of the combination of predetermined hue and saturation to the overall image area of the captured image data, respectively; and
   a photographed scene estimating means for estimating a photographed scene, based on the calculated occupation ratio for every brightness area, the calculated occupation ratio for every hue area, the calculated occupation ratio for every divided area consisting of the combination of predetermined hue, saturation and brightness and the average brightness value.
(Item 49) An image-recording apparatus, characterized in that,
   in the image-recording apparatus for inputting captured image data to generate image data optimized for viewing an output image on an outputting medium and for forming the output image based on the image data on the outputting medium, the image-recording apparatus is provided with:
   a data acquiring means for acquiring a hue value and a brightness value for every pixel included in the captured image data;
   a brightness area dividing means for dividing the captured image data into predetermined brightness areas;
   an HV dividing means for dividing the captured image data into areas each of which consists of a combination of predetermined hue and brightness;
   a brightness area occupation ratio calculating means for calculating occupation ratios each of which indicates a ratio of the pixels for every brightness area divided in the above to an overall image area of the captured image data, respectively;
   an HV occupation ratio calculating means for calculating occupation ratios each of which indicates a ratio of the pixels for every divided area consisting of the combination of predetermined hue and brightness to the overall image area of the captured image data, respectively;
   a photographed scene estimating means for estimating a photographed scene, based on the calculated occupation ratio for every brightness area and the occupation ratio for every divided area consisting of the combination of predetermined hue and brightness;
   a face area extracting means for extracting a face area of the captured image data;
   a contribution ratio determining means for determining a contribution ratio of the face area for a gradation conversion processing, based on the photographed scene estimated in the above; and
   a gradation conversion processing means for applying the gradation conversion processing to the captured image data, based on the contribution ratio determined in the above.
(Item 50) An image-recording apparatus, characterized in that,
   in the image-recording apparatus for inputting captured image data to generate image data optimized for viewing an output image on an outputting medium and for forming the output image based on the image data on the outputting medium, the image-recording apparatus is provided with:
   a data acquiring means for acquiring a hue value, a brightness value and saturation value for every pixel included in the captured image data;
   a brightness area dividing means for dividing the captured image data into predetermined brightness areas;
   a hue area dividing means for dividing the captured image data into predetermined hue areas;
   an HS dividing means for dividing the captured image data into areas each of which consists of a combination of predetermined hue and saturation;
   a brightness-area occupation ratio calculating means for calculating occupation ratios each of which indicates a ratio of the pixels for every brightness area divide in the above to an overall image area of the captured image data, respectively;
   a hue-area occupation ratio calculating means for calculating occupation ratios each of which indicates a ratio of the pixels for every hue area divided in the above to an overall image area of the captured image data, respectively;
   an average brightness value calculating means for calculating an average brightness value for every divided area consisting of the combination of predetermined hue and saturation to the overall image area of the captured image data, respectively;
   a photographed scene estimating means for estimating a photographed scene, based on the calculated occupation ratio for every brightness area, the calculated occupation ratio for every hue area and the average brightness value;
   a face area extracting means for extracting a face area of the captured image data;
   a contribution ratio determining means for determining a contribution ratio of the face area for a gradation conversion processing, based on the photographed scene estimated in the above; and
   a gradation conversion processing means for applying the gradation conversion processing to the captured image data, based on the contribution ratio determined in the above.
(Item 51) An image-recording apparatus, characterized in that,
   in the image-recording apparatus for inputting captured image data to generate image data optimized for viewing an output image on an outputting medium and for forming the output image based on the image data on the outputting medium, the image-recording apparatus is provided with:
   a data acquiring means for acquiring a hue value, a brightness value and saturation value for every pixel included in the captured image data;
   a brightness area dividing means for dividing the captured image data into predetermined brightness areas;
   an HSV dividing means for dividing the captured image data into areas each of which consists of a combination of predetermined hue, saturation and brightness;
   a brightness-area occupation ratio calculating means for calculating occupation ratios each of which indicates a ratio of the pixels for every brightness area divided in the above to an overall image area of the captured image data, respectively;
   an HSV occupation ratio calculating means for calculating occupation ratios each of which indicates a ratio of the pixels for every divided area consisting of the combination of predetermined hue, saturation and brightness to the overall image area of the captured image data, respectively;
   a photographed scene estimating means for estimating a photographed scene, based on the calculated occupation ratio for every brightness area and the occupation ratio for every divided area consisting of the combination of predetermined hue, saturation and brightness;
   a face area extracting means for extracting a face area of the captured image data;
   a contribution ratio determining means for determining a contribution ratio of the face area for a gradation conversion processing, based on the photographed scene estimated in the above; and
   a gradation conversion processing means for applying the gradation conversion processing to the captured image data, based on the contribution ratio determined in the above.
(Item 52) An image-recording apparatus, characterized in that,
   in the image-recording apparatus for inputting captured image data to generate image data optimized for viewing an output image on an outputting medium and for forming the output image based on the image data on the outputting medium, the image-recording apparatus is provided with:
   a data acquiring means for acquiring a hue value, a brightness value and saturation value for every pixel included in the captured image data;
   a brightness area dividing means for dividing the captured image data into predetermined brightness areas;
   a hue area dividing means for dividing the captured image data into predetermined hue areas;
   an HSV dividing means for dividing the captured image data into areas each of which consists of a combination of predetermined hue, saturation and brightness;
   an HS dividing means for dividing the captured image data into areas each of which consists of a combination of predetermined hue and saturation;
   a brightness-area occupation ratio calculating means for calculating occupation ratios each of which indicates a ratio of the pixels for every brightness area divide in the above to an overall image area of the captured image data, respectively;
   a hue-area occupation ratio calculating means for calculating occupation ratios each of which indicates a ratio of the pixels for every hue area divided in the above to an overall image area of the captured image data, respectively;
   an HSV occupation ratio calculating means for calculating occupation ratios each of which indicates a ratio of the pixels for every divided area consisting of the combination of predetermined hue, saturation and brightness to the overall image area of the captured image data, respectively;
   an average brightness value calculating means for calculating an average brightness value for every divided area consisting of the combination of predetermined hue and saturation to the overall image area of the captured image data, respectively;
   a photographed scene estimating means for estimating a photographed scene, based on the calculated occupation ratio for every brightness area, the calculated occupation ratio for every hue area, the calculated occupation ratio for every divided area consisting of the combination of predetermined hue, saturation and brightness and the average brightness value;
   a face area extracting means for extracting a face area of the captured image data;
   a contribution ratio determining means for determining a contribution ratio of the face area for a gradation conversion processing, based on the photographed scene estimated in the above; and
   a gradation conversion processing means for applying the gradation conversion processing to the captured image data, based on the contribution ratio determined in the above.
(Item 53) The image-recording apparatus, described in item 45 or 49, characterized in that,
   the brightness area dividing means divides the captured image data into a shadow area having a brightness value in a range of 0-84, an intermediate area having a brightness value in a range of 85-169 and a highlighted area having a brightness value in a range of 170-255, each as a value defined by the HSV color specification system, and
   the HV dividing means divides the captured image data into a flesh-color shadow area having a hue value in a range of 0-69 and a brightness value in a range of 0-84, a flesh-color intermediate area having a hue value in a range of 0-69 and a brightness value in a range of 85-169 and a flesh-color highlighted area having a hue value in a range of 0-69 and a brightness value in a range of 170-255, each as a value defined by the HSV color specification system.
(Item 54) The image-recording apparatus, described in item 46 or 50, characterized in that,
   the brightness area dividing means divides the captured image data into a shadow area having a brightness value in a range of 0-84, an intermediate area having a brightness value in a range of 85-169 and a highlighted area having a brightness value in a range of 170-255, each as a value defined by the HSV color specification system, and
   the hue area dividing means divides the captured image data into a flesh-color hue area having a hue value in a range of 0-69, a green hue area having a hue value in a range of 70-184, a sky-blue hue area having a hue value in a range of 185-224 and a red hue area having a hue value in a range of 225-360, each as a value defined by the HSV color specification system, and
   the HS dividing means divides the captured image data into at least a flesh-color area having a hue value in a range of 0-69 and a saturation value in a range of 0-128, each as a value defined by the HSV color specification system.
(Item 55) The image-recording apparatus, described in item 47 or 51, characterized in that,
   the brightness area dividing means divides the captured image data into a shadow area having a brightness value in a range of 0-84, an intermediate area having a brightness value in a range of 85-169 and a highlighted area having a brightness value in a range of 170-255, each as a value defined by the HSV color specification system, and
   the HSV dividing means divides the captured image data into a flesh-color shadow area having a hue value in a range of 0-69, a saturation value in a range of 0-128 and a brightness value in a range of 0-84, a flesh-color intermediate area having a hue value in a range of 0-69, a saturation value in a range of 0-128 and a brightness value in a range of 85-169, and a flesh-color highlighted area having a hue value in a range of 0-69, a saturation value in a range of 0-128 and a brightness value in a range of 170-255, each as a value defined by the HSV color specification system.
(Item 56) The image-recording apparatus, described in item 48 or 52, characterized in that,
   the brightness area dividing means divides the captured image data into a shadow area having a brightness value in a range of 0-84, an intermediate area having a brightness value in a range of 85-169 and a highlighted area having a brightness value in a range of 170-255, each as a value defined by the HSV color specification system, and
   the hue area dividing means divides the captured image data into a flesh-color hue area having a hue value in a range of 0-69, a green hue area having a hue value in a range of 70-184, a sky-blue hue area having a hue value in a range of 185-224 and a red hue area having a hue value in a range of 225-360, each as a value defined by the HSV color specification system, and
   the HSV dividing means divides the captured image data into a flesh-color shadow area having a hue value in a range of 0-69, a saturation value in a range of 0-128 and a brightness value in a range of 0-84, a flesh-color intermediate area having a hue value in a range of 0-69, a saturation value in a range of 0-128 and a brightness value in a range of 85-169, and a flesh-color highlighted area having a hue value in a range of 0-69, a saturation value in a range of 0-128 and a brightness value in a range of 170-255, each as a value defined by the HSV color specification system, and
   the HS dividing means divides the captured image data into a flesh-color area having a hue value in a range of 0-69 and a saturation value in a range of 0-128, each as a value defined by the HSV color specification system.
(Item 57) The image-recording apparatus, described in any one of items 45, 49 and 53, characterized in that,
   the image-recording apparatus is further provided with a two-dimensional histogram creating means for creating a two-dimensional histogram of the hue value and the brightness value acquired previously, and
   based on the two-dimensional histogram created in the above, the brightness area dividing means divides the captured image data into the predetermined brightness areas and,
   based on the two-dimensional histogram created in the above, the HV dividing means divides the captured image data into the areas each of which consists of the combination of predetermined brightness area and the predetermined hue area.
(Item 58) The image-recording apparatus, described in any one of items 46, 50 and 54, characterized in that,
   the image-recording apparatus is further provided with a three-dimensional histogram creating means for creating a three-dimensional histogram of the hue value and the brightness value acquired previously, and
   based on the three-dimensional histogram created in the above, the brightness area dividing means divides the captured image data into the predetermined brightness areas and,
   based on the three-dimensional histogram created in the above, the hue area dividing means divides the captured image data into the predetermined hue areas and,
   based on the three-dimensional histogram created in the above, the HS dividing means divides the captured image data into the areas each of which consists of the combination of predetermined hue and saturation.
(Item 59) The image-recording apparatus, described in any one of items 47, 51 and 55, characterized in that,
   the image-recording apparatus is further provided with a three-dimensional histogram creating means for creating a three-dimensional histogram of the hue value and the brightness value acquired previously, and
   based on the three-dimensional histogram created in the above, the brightness area dividing means divides the captured image data into the predetermined brightness areas and,
   based on the three-dimensional histogram created in the above, the HSV dividing means divides the captured image data into the areas each of which consists of the combination of predetermined hue, saturation and brightness.
(Item 60) The image-recording apparatus, described in any one of items 48, 52 and 56, characterized in that,
   the image-recording apparatus is further provided with a three-dimensional histogram creating means for creating a three-dimensional histogram of the hue value and the brightness value acquired previously, and
   based on the three-dimensional histogram created in the above, the brightness area dividing means divides the captured image data into the predetermined brightness areas and,
   based on the three-dimensional histogram created in the above, the hue area dividing means divides the captured image data into the predetermined hue areas and,
   based on the three-dimensional histogram created in the above, the HSV dividing means divides the captured image data into the areas each of which consists of the combination of predetermined hue, saturation and brightness.
   based on the three-dimensional histogram created in the above, the HS dividing means divides the captured image data into the areas each of which consists of the combination of predetermined hue and saturation.
(Item 61) The image-recording apparatus, described in any one of items 49-60, characterized in that,
   the face area extracting means extracts an area consisting of the combination of predetermined hue and saturation in the captured image data as the face area.
(Item 62) The image-recording apparatus, described in item 61, characterized in that,
   the face area extracting means creates a two-dimensional histogram of the hue value and the saturation value in the captured image data, and extracts the area consisting of the combination of predetermined hue and saturation as the face area, based on the two-dimensional histogram created in the above.
(Item 63) The image-recording apparatus, described in item 61 or 62, characterized in that,
   the area consisting of the combination of predetermined hue and saturation, to be extracted as the face area, is such an area having a hue value in a range of 0-50 and a brightness value in a range of 10-120, each as a value defined by the HSV color specification system in the captured image data.
(Item 64) The image-recording apparatus, described in any one of items 49-63, characterized in that,
   the gradation conversion processing means applies the gradation conversion processing to the captured image data by conducting the steps of: calculating an average brightness input value, based on the contribution ratio of the face area; adjusting a gradation conversion curve either by creating a new gradation conversion curve for converting the average brightness input value to a target conversion value of average brightness value established in advance or by selecting a suitable one out of a plurality of gradation conversion curves established in advance; and employing the gradation conversion curve adjusted in the above step.
(Item 65) The image-recording apparatus, described in any one of items 45-64, characterized in that,
   the captured image data are scene-referred image data.
(Item 66) The image-recording apparatus, described in any one of items 45-65, characterized in that,
   the image data optimized for viewing the output image on the outputting medium are output-referred image data.

Incidentally, the term of “captured image data”, described in the present specification, is defined as digital image data that represent subject image information in a form of electronic signals. Any kind of process can be employed for acquiring the digital image data, for instance, such as generating the digital image data by scanning a color photographic film to read dye-image information recoded in the film, generating the digital image data by means of the digital camera, etc.

However, when generating the digital image data from a color negative film by reading it with a scanner, it is desirable that the calibration of the maximum transmitted light amount and the reversal processing are applied to the film so as to make all of the RGB values, of the digital image data at the non-exposed area (minimum density area) of the color negative film, zero, and then, by applying the conversion processing for converting the scale in direct proportion to the maximum transmitted light amount to the logarithmic (density) scale and the gamma correction processing of the color negative film, a state of being substantially in proportion to the intensity change of the subject is reproduced in advance. Further, it is also desirable that the RGB values of the digital image data representing an image captured by the digital camera are substantially in proportion to the intensity change of the subject as well. Still further, it is also desirable that the digital image data are the “scene-referred image data”.

The term of “scene-referred image data” means such image data that at least signal intensities of each color channel based on the spectral sensitivity of the image-capturing device itself are already mapped on the standard color space, such as the RIMM RGB (Reference Input Medium Metric RGB), the ERIMM RGB (Extended Reference Input Medium Metric RGB), etc., and in a state that the image-processing, for changing the contents of the image data to improve the effect at the time of viewing the image, such as the gradation conversion processing, the sharpness enhancement processing and the saturation enhancement processing, are omitted. Further, it is desirable that the scene-referred image data are already processed with the correction processing of the opto-electronic conversion characteristics of the image-capturing apparatus (namely, the opto-electronic conversion function defined by ISO1452, set forth in, for instance, “Fine imaging and digital photographing” edited by the Publishing Commission of the Japan Society of Electrophotography, Corona Publishing Co., P. 479). Conforming to the efficiency of the A/D converter, it is desirable that the information content of the standardized scene-referred image data (for instance, a number of gradation steps) is equal to or greater than that (for instance, a number of gradation steps) required for the “output-referred image data” detailed later. For instance, when the number of gradation steps for the output-referred image data is set at 8 bits, it is desirable that a corresponding number of gradation steps for the scene-referred image data is set at more than 12 bits, more desirable that set at more than 14 bits and further more desirable that set at more than 16 bits.

The term of “optimized for viewing an output image on an outputting medium” means processing operations for acquiring an optimized image on a display device, such as a CRT (Cathode Ray Tube), a liquid crystal display, a plasma display, etc., or an outputting medium, such as a silver-halide photosensitive paper, an ink-jet paper, a thermal-printer paper, etc. For instance, when it is premised that the output image is displayed on a CRT display monitor conforming to the sRGB standard, the scene-referred image data would be processed so as to acquire an optimized color reproduction within the color region specified by the sRGB standard. While, when it is premised that the output image is outputted onto a silver-halide photosensitive paper, the scene-referred image data would be processed so as to acquire an optimized color reproduction within the color region of the silver-halide photosensitive paper. Further, other than the compression processing of the color region, the abovementioned processing operations includes a gradation compression processing from 16 bits to 8 bits, a reducing processing of a number of output pixels, a processing operation corresponding to an output characteristic (LUT) of the output device, etc. In addition to the above, it is needless to say that a noise suppression processing, a sharpness enhancement, a gray balance adjustment, a saturation adjustment, and a gradation compression processing, such as a dodging operation, etc., would be conducted.

The term of “image data optimized for viewing an output image on an outputting medium” means digital image data employed for forming an output image on a display device, such as a CRT (Cathode Ray Tube), a liquid crystal display, a plasma display, etc., or an outputting medium, such as a silver-halide photosensitive paper, an ink-jet paper, a thermal-printer paper, etc. Accordingly, the digital image data are processed so as to acquire an optimum image on a display device, such as a CRT (Cathode Ray Tube), a liquid crystal display, a plasma display, etc., or an outputting medium, such as a silver-halide photosensitive paper, an ink-jet paper, a thermal-printer paper, etc. When the “captured image data” are defined as the “scene-referred image data”, the “image data optimized for viewing an output image on an outputting medium” are denoted as the “output-referred image data”.

Further, in the descriptions of the present invention, the dividing manners of the captured image data are determined on the basis of results of the survey. For instance, when dividing the captured image data into the hue areas, with respect to about 1000 film-scanning image frames, the hue areas were calculated from the result of examining such a hue range that the detecting rates of a human fresh color, a green color of plants and a sky color became the highest. With respect to the border values for dividing the borders of the brightness areas, after scenes captured under conditions of backlight, strobe lighting, etc. were defined in advance, respectively, the border values were determined by conducting the survey as well as the above. When implementing the present invention, it is desirable that the aforementioned value limitation would be changed, with respect to each of the film-scanning image and the captured image of the digital camera.

Here, in the present invention, the term “brightness” means “lightness” used generally as far as remarks are specially not provided. In the below description, for the convenience in explanation, the lightness is uniformly represented by the term “brightness” with V(0-255) of HSV color specification system. Therefore, the lightness represented by a value of the HSV color specification system basis may be represented by the lightness of another possible color specification system. In this case, the value of the HSV color specification system basis and the coefficient represented by the HSV color specification system basis may be changed in accordance with the adopted color specification system.

According to the present invention described in Items 1, 23, 45, since the photographed scene is estimated on the basis of the occupation ratio for every area, which consists of a combination of predetermined hue and brightness, in addition to the occupation ratio for every brightness area in the captured image data, it becomes possible to improve an accuracy of the estimation result of the photographed scene.

According to the present invention described in Items 5, 27, 49, since the photographed scene is estimated on the basis of the occupation ratio for every area, which consists of a combination of predetermined hue and brightness, in addition to the occupation ratio for every brightness area in the captured image data, it becomes possible to improve an accuracy of the estimation result of the photographed scene. Further, since the gradation processing includes the steps of: extracting the face area of the inputted image data; determining the contribution ratio of the face area based on the photographed scene estimated in the above; determining the gradation conversion curve based on the contribution ratio determined in the above; and applying the gradation conversion processing to the inputted image data by employing the gradation conversion curve determined in the above, it becomes possible to apply the appropriate gradation processing.

According to the present invention described in Items 1, 5, 23, 27, 45, 49, it is desirable that the captured image data are divided into the shadow area having a brightness value in a range of 0-84, the intermediate area having a brightness value in a range of 85-169 and the highlighted area having a brightness value in a range of 170-255, each as a value defined by the HSV color specification system, and at the same time, the captured image data are divided into the flesh-color shadow area having a hue value in a range of 0-69 and a brightness value in a range of 0-84, the flesh-color intermediate area having a hue value in a range of 0-69 and a brightness value in a range of 85-169, and the flesh-color highlighted area having a hue value in a range of 0-69 and a brightness value in a range of 170-255, each as a value defined by the HSV color specification system. According to the above, since the empirical rule of the magnitude relationships between shadow, intermediate and highlighted areas in the flesh-color hue area are added to the magnitude relationships between shadow, intermediate and highlighted areas, it becomes possible to obtain more high-accurate estimation result than ever.

Further, according to the present invention described in Items 1, 23, 45, it is also desirable that the area dividing processing is conducted by creating the two-dimensional histogram of the hue and brightness values of the captured image data. Still further, according to the present invention described in Items 5, 27, 49, it is also desirable that the area dividing processing is conducted by creating the three-dimensional histogram of the hue, saturation and brightness values of the captured image data. According to the above, it becomes possible to efficiently conduct the area dividing operation.

According to the present invention described in Items 5, 27, 49, by extracting the area, which consists of a combination of predetermined hue and saturation in the captured image data, as the face area, it becomes possible to easily conduct the extracting operation of the face area. To make the extracting operation efficient, after creating the two-dimensional histogram of the hue and saturation values of the captured image data, the area, which consists of a combination of predetermined hue and saturation, is extracted on the basis of the created two-dimensional histogram. Further, by setting the area to be extracted at such a area that consists of a combination of a hue value in a range of 0-50 and a saturation value in a range of 10-120, it becomes possible to extract an appropriate face area. It is possible to create the gradation conversion curve, to be employed for the gradation conversion processing, based on the contribution ratio of the face area, every time when new image data are inputted. Alternatively, it is also possible to select a suitable one out of a plurality of gradation conversion curves established in advance.

According to the present invention described in Items 2, 24, 46, since the photographed scene is estimated on the basis of the occupation ratio for every brightness area, the occupation ratio for every hue area, and the average brightness value of the area, which consists of a combination of predetermined hue and saturation, it becomes possible to improve an accuracy of the estimation result of the photographed scene.

According to the present invention described in Items 6, 28, 50, since the photographed scene is estimated on the basis of the occupation ratio for every area, which consists of a combination of predetermined hue and brightness, in addition to the occupation ratio for every brightness area in the captured image data, it becomes possible to improve an accuracy of the estimation result of the photographed scene. Further, since the gradation processing includes the steps of: extracting the face area of the inputted image data; determining the contribution ratio of the face area based on the photographed scene estimated in the above; determining the gradation conversion curve based on the contribution ratio determined in the above; and applying the gradation conversion processing to the inputted image data by employing the gradation conversion curve determined in the above, it becomes possible to apply the appropriate gradation processing.

According to the present invention described in Items 2, 6, 24, 28, 46, 50, it is desirable that the captured image data are divided into the shadow area having a brightness value in a range of 0-84, the intermediate area having a brightness value in a range of 85-169 and the highlighted area having a brightness value in a range of 170-255, each as a value defined by the HSV color specification system, to calculate the occupation ratio of each area, and the captured image data are divided into the flesh-color hue area having a hue value in a range of 0-69, the green hue area having a hue value in a range of 70-184, the sky-blue hue area having a hue value in a range of 185-224 and a red hue area having a hue value in a range of 225-360, each as a value defined by the HSV color specification system, to calculate the occupation ratio of each area, and the captured image data are divided into the flesh-color area having a hue value in a range of 0-69 and a saturation value in a range of 0-128, each as a value defined by the HSV color specification system, to calculate its average brightness value. According to the above, since the empirical rule of the occupation ratio for each of the green hue area and the sky-blue hue area, and the empirical rule of the average brightness value of the flesh-color hue area in each photographed scene are added to the magnitude relationships between shadow, intermediate and highlighted areas, it becomes possible to obtain more high-accurate estimation result than ever. Further, it is also desirable that the captured image data are divided into the areas by creating the three-dimensional histogram of the hue, saturation and brightness values of the captured image data. According to the above, it becomes possible to efficiently divide the captured image data into the areas.

According to the present invention described in Items 6, 28, 50, by extracting the area, which consists of a combination of predetermined hue and saturation in the captured image data, as the face area, it becomes possible to easily conduct the extracting operation of the face area. To make the extracting operation efficient, after creating the two-dimensional histogram of the hue and saturation values of the captured image data, the area, which consists of a combination of predetermined hue and saturation, is extracted on the basis of the created two-dimensional histogram. Further, by setting the area to be extracted at such a area that consists of a combination of a hue value in a range of 0-50 and a saturation value in a range of 10-120, it becomes possible to extract an appropriate face area. It is possible to create the gradation conversion curve, to be employed for the gradation conversion processing, based on the contribution ratio of the face area, every time when new image data are inputted. Alternatively, it is also possible to select a suitable one out of a plurality of gradation conversion curves established in advance.

According to the present invention described in Items 3, 25, 47, since the photographed scene is estimated on the basis of the occupation ratio for every brightness area and the occupation ratio for every area, which consists of a combination of predetermined hue, saturation and brightness, it becomes possible to improve an accuracy of the estimation result of the photographed scene.

According to the present invention described in Items 7, 29, 51, since the photographed scene is estimated on the basis of the occupation ratio for every area, which consists of a combination of predetermined hue and brightness, in addition to the occupation ratio for every brightness area in the captured image data, it becomes possible to improve an accuracy of the estimation result of the photographed scene. Further, since the gradation processing includes the steps of: extracting the face area of the inputted image data; determining the contribution ratio of the face area based on the photographed scene estimated in the above; determining the gradation conversion curve based on the contribution ratio determined in the above; and applying the gradation conversion processing to the inputted image data by employing the gradation conversion curve determined in the above, it becomes possible to apply the appropriate gradation processing.

According to the present invention described in Items 3, 7, 25, 29, 47, 51, it is desirable that the captured image data are divided into the shadow area having a brightness value in a range of 0-84, the intermediate area having a brightness value in a range of 85-169 and the highlighted area having a brightness value in a range of 170-255, each as a value defined by the HSV color specification system, to calculate the occupation ratio of each area, and the captured image data are divided into a flesh-color shadow area having a hue value in a range of 0-69, a saturation value in a range of 0-128 and a brightness value in a range of 0-84, a flesh-color intermediate area having a hue value in a range of 0-69, a saturation value in a range of 0-128 and a brightness value in a range of 85-169, and a flesh-color highlighted area having a hue value in a range of 0-69, a saturation value in a range of 0-128 and a brightness value in a range of 170-255, each as a value defined by the HSV color specification system to calculate the occupation ratio of each area. According to the above, since the empirical rule of the magnitude relationships between shadow, intermediate and highlighted areas in the flesh-color hue area of each photographed scene is added to the magnitude relationships between shadow, intermediate and highlighted areas, it becomes possible to obtain more high-accurate estimation result than ever. Further, it is also desirable that the captured image data are divided into the areas by creating the three-dimensional histogram of the hue, saturation and brightness values of the captured image data.

According to the above, it becomes possible to efficiently conduct the processing. According to the present invention described in Items 7, 29, 51, by extracting the area, which consists of a combination of predetermined hue and saturation in the captured image data, as the face area, it becomes possible to easily conduct the extracting operation of the face area. To make the extracting operation efficient, after creating the two-dimensional histogram of the hue and saturation values of the captured image data, the area, which consists of a combination of predetermined hue and saturation, is extracted on the basis of the created two-dimensional histogram. Further, by setting the area to be extracted at such a area that consists of a combination of a hue value in a range of 0-50 and a saturation value in a range of 10-120, it becomes possible to extract an appropriate face area. It is possible to create the gradation conversion curve, to be employed for the gradation conversion processing, based on the contribution ratio of the face area, every time when new image data are inputted. Alternatively, it is also possible to select a suitable one out of a plurality of gradation conversion curves established in advance.

According to the present invention described in Items 4, 26, 48, since the photographed scene is estimated on the basis of the relationship of the occupation ratio for every brightness area, the relationship of the occupation ratio for every hue area, the relationship of the occupation ratio for every area, which consists of a combination of predetermined hue, saturation and brightness, and the average brightness value, which consists of a combination of predetermined hue and saturation, it becomes possible to improve an accuracy of the estimation result of the photographed scene.

Further, according to the present invention described in Items 8, 30, 52, since the photographed scene is estimated on the basis of the occupation ratio for every brightness area, the occupation ratio for every hue area, the occupation ratio for every area, which consists of a combination of predetermined hue, saturation and brightness, and the average brightness value, which consists of a combination of predetermined hue and saturation, it becomes possible to improve an accuracy of the estimation result of the photographed scene. Further, since the gradation processing includes the steps of: extracting the face area of the inputted image data; determining the contribution ratio of the face area based on the photographed scene estimated in the above; determining the gradation conversion curve based on the contribution ratio determined in the above; and applying the gradation conversion processing to the inputted image data by employing the gradation conversion curve determined in the above, it becomes possible to apply the appropriate gradation processing.

According to the present invention described in Items 4, 8, 26, 30, 48, 52, it is desirable that the captured image data are divided into the shadow area having a brightness value in a range of 0-84, the intermediate area having a brightness value in a range of 85-169 and the highlighted area having a brightness value in a range of 170-255, each as a value defined by the HSV color specification system, to calculate the occupation ratio of each area, and the captured image data are divided into the flesh-color hue area having a hue value in a range of 0-69, the green hue area having a hue value in a range of 70-184, the sky-blue hue area having a hue value in a range of 185-224 and a red hue area having a hue value in a range of 225-360, each as a value defined by the HSV color specification system, to calculate the occupation ratio of each area, and the captured image data are divided into a flesh-color shadow area having a hue value in a range of 0-69, a saturation value in a range of 0-128 and a brightness value in a range of 0-84, a flesh-color intermediate area having a hue value in a range of 0-69, a saturation value in a range of 0-128 and a brightness value in a range of 85-169, and a flesh-color highlighted area having a hue value in a range of 0-69, a saturation value in a range of 0-128 and a brightness value in a range of 170-255, each as a value defined by the HSV color specification system to calculate the occupation ratio of each area, and the captured image data are divided into the flesh-color area having a hue value in a range of 0-69 and a saturation value in a range of 0-128, each as a value defined by the HSV color specification system, to calculate its average brightness value. According to the above, since the empirical rule of the occupation ratio for each of the green hue area and the sky-blue hue area, the empirical rule of the magnitude relationships between shadow, intermediate and highlighted areas in the flesh-color area and the empirical rule of the average brightness value of the flesh-color hue area in each photographed scene are added to the magnitude relationships between shadow, intermediate and highlighted areas, it becomes possible to obtain more high-accurate estimation result than ever. Further, it is also desirable that the captured image data are divided into the areas by creating the three-dimensional histogram of the hue, saturation and brightness values of the captured image data. According to the above, it becomes possible to efficiently divide the captured image data into the areas.

According to the present invention described in Items 8, 30, 52, by extracting the area, which consists of a combination of predetermined hue and saturation in the captured image data, as the face area, it becomes possible to easily conduct the extracting operation of the face area. To make the extracting operation efficient, after creating the two-dimensional histogram of the hue and saturation values of the captured image data, the area, which consists of a combination of predetermined hue and saturation, is extracted on the basis of the created two-dimensional histogram. Further, by setting the area to be extracted at such a area that consists of a combination of a hue value in a range of 0-50 and a saturation value in a range of 10-120, it becomes possible to extract an appropriate face area. It is possible to create the gradation conversion curve, to be employed for the gradation conversion processing, based on the contribution ratio of the face area, every time when new image data are inputted. Alternatively, it is also possible to select a suitable one out of a plurality of gradation conversion curves established in advance.

Further, according to the present invention, by conducting the steps of: inputting the captured image data as the scene-referred image data; and converting the scene-referred image data to the output-referred image data by applying the optimization processing including the aforementioned photographed scene estimation processing and the gradation conversion processing to the scene-referred image data, so that an optimized output image can be acquired on an output medium (such as a CRT, a liquid-crystal display, a plasma display, a silver-halide photosensitive paper, an ink-jet paper, a thermal-printing paper, etc.), it becomes possible to form the optimized output image based on the output-referred image data without loosing any information included in the originally-photographed image information.

### First Embodiment

Referring to the drawings, the first embodiment of the present invention will be detailed in the following. Initially, the configuration of the first embodiment will be detailed in the following.

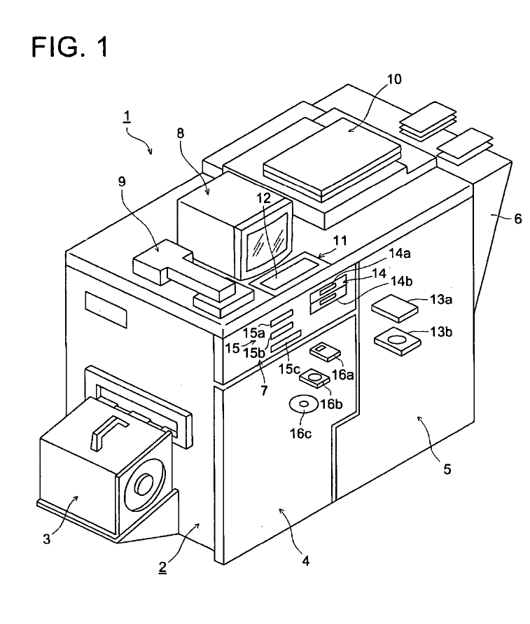

FIG. 1 shows a perspective view of the outlook structure of image-recording apparatus 1 embodied in the present invention. As shown in FIG. 1, image-recording apparatus 1 is provided with magazine loading section 3 mounted on a side of housing body 2, exposure processing section 4, for exposing a photosensitive material, mounted inside housing body 2 and print creating section 5 for creating a print. Further, tray 6 for receiving ejected prints is installed on another side of housing body 2.

Still further, CRT 8 (Cathode Ray Tube 8) serving as a display device, film scanning section 9 serving as a device for reading a transparent document, reflected document input section 10 and operating section 11 are provided on the upper side of housing body 2. CRT 8 serves as the display device for displaying the image represented by the image information to be created as the print. Further, image reading section 14 capable of reading image information recorded in various kinds of digital recording mediums and image writing section 15 capable of writing (outputting) image signals onto various kinds of digital recording mediums are provided in housing body 2. Still further, control section 7 for centrally controlling the abovementioned sections is also provided in housing body 2.

Image reading section 14 is provided with PC card adaptor 14a, floppy (Registered Trade Mark) disc adaptor 14b, into each of which PC card 13a and floppy disc 13b can be respectively inserted. For instance, PC card 13a has storage for storing the information with respect to a plurality of frame images captured by the digital still camera. Further, for instance, a plurality of frame images captured by the digital still camera are stored in floppy (Registered Trade Mark) disc 13b. Other than PC card 13a and floppy (Registered Trade Mark) disc 13b, a multimedia card (Registered Trade Mark), a memory stick (Registered Trade Mark), MD data, CD-ROM, etc., can be cited as recording media in which frame image data can be stored.

Image writing section 15 is provided with floppy (Registered Trade Mark) disk adaptor 15a, MO adaptor 15b and optical disk adaptor 15c, into each of which FD 16a, MO 16b and optical disc 16c can be respectively inserted. Further, CD-R, DVD-R, etc. can be cited as optical disc 16c.

Incidentally, although, in the configuration shown in FIG. 1, operating section 11, CRT 8, film scanning section 9, reflected document input section 10 and image reading section 14 are integrally provided in housing body 2, it is also applicable that one or more of them is separately disposed outside housing body 2.

Further, although image-recording apparatus 1, which creates a print by exposing/developing the photosensitive material, is exemplified in FIG. 1, the scope of the print creating method in the present invention is not limited to the above, but an apparatus employing any kind of methods, including, for instance, an ink-jetting method, an electrophotographic method, a heat-sensitive method and a sublimation method, is also applicable in the present invention.

Functional Configuration of Image-Recording Apparatus 1

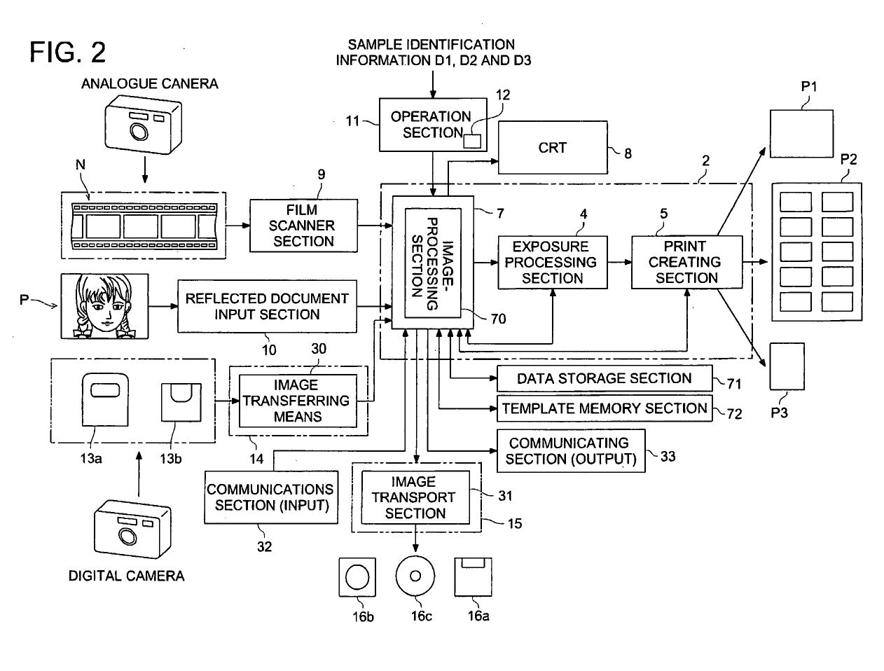

FIG. 2 shows a block diagram of the functional configuration of image-recording apparatus 1. Referring to FIG. 2, the functional configuration of image-recording apparatus 1 will be detailed in the following.

Control section 7 includes a microcomputer to control the various sections constituting image-recording apparatus 1 by cooperative operations of CPU (Central Processing Unit) (not shown in the drawings) and various kinds of controlling programs, including an image-processing program, etc., stored in a storage section (not shown in the drawings), such as ROM (Read Only Memory), etc.

Further, control section 7 is provided with image-processing section 70, relating to the image-processing apparatus embodied in the present invention, which applies the image processing of the present invention to image data acquired from film scanning section 9 and reflected document input section 10, image data read from image reading section 14 and image data inputted from an external device through communicating section 32 (input), based on the input signals (command information) sent from operating section 11, to generate the image information of exposing use, which are outputted to exposure processing section 4. Further, image-processing section 70 applies the conversion processing corresponding to its output mode to the processed image data, so as to output the converted image data. Image-processing section 70 outputs the converted image data to CRT 8, image writing section 15, communicating section 33 (output), etc.

Exposure processing section 4 exposes the photosensitive material based on the image signals, and outputs the photosensitive material to print creating section 5. In print creating section 5, the exposed photosensitive material is developed and dried to create prints P1, P2, P3. Incidentally, prints P1 include service size prints, high-vision size prints, panorama size prints, etc., prints P2 include A4-size prints, and prints P3 include visiting card size prints.

Film scanning section 9 reads the frame image data from developed negative film N acquired by developing the negative film having an image captured by an analogue camera. Reflected document input section 10 reads the frame image data from print P (such as photographic prints, paintings and calligraphic works, various kinds of printed materials) made of a photographic printing paper on which the frame image is exposed and developed, by means of the flat bed scanner.

Image reading section 14 reads the frame image information stored in PC card 13a and floppy (Registered Trade Mark) disc 13b to transfer the acquired image information to control section 7. Further, image reading section 14 is provided with PC card adaptor 14a, floppy disc adaptor 14b serving as an image transferring means 30. Still further, image reading section 14 reads the frame image information stored in PC card 13a inserted into PC card adaptor 14a and floppy disc 13b inserted into floppy disc adaptor 14b to transfer the acquired image information to control section 7. For instance, the PC card reader or the PC card slot, etc. can be employed as PC card adaptor 14a.

Communicating section 32 (input) receives image signals representing the captured image and print command signals sent from a separate computer located within the site in which image-recording apparatus 1 is installed and/or from a computer located in a remote site through Internet, etc.

Image writing section 15 is provided with floppy disk adaptor 15a, MO adaptor 15b and optical disk adaptor 15c, serving as image conveying section 31. Further, according to the writing signals inputted from control section 7, image writing section 15 writes the data, generated by the image-processing method embodied in the present invention, into floppy disk 16a inserted into floppy disk adaptor 15a, MO disc 1 Gb inserted into MO adaptor 15b and optical disk 16c inserted into optical disk adaptor 15c.

Data storage section 71 stores the image information and its corresponding order information (including information of a number of prints and a frame to be printed, information of print size, etc.) to sequentially accumulate them in it.

The template memory section 72 memorizes the sample image data (data showing the background image and illustrated image) corresponding to the types of information on sample identification D1, D2 and D3, and memorizes at least one of the data items on the template for setting the composite area with the sample image data. When a predetermined template is selected from among multiple templates previously memorized in the template memory section 72 by the operation of the operator, the selected template is merged with the frame image information. Then, the sample image data, selected on the basis of designated sample identification information D1, D2 and D3, are merged with image data and/or character data ordered by a client, so as to create a print based on the designated sample image. This merging operation by this template is performed by the widely known chromakey technique.

The types of information on sample identification D1, D2 and D3 for specifying the print sample are arranged to be inputted from the operation section 11. Since the types of information on sample identification D1, D2 and D3 are recorded on the sample or order sheet, they can be read by the reading section such as an OCR. Alternatively, they can be inputted by the operator through a keyboard.

As described above, sample image data is recorded in response to sample identification information D1 for specifying the print sample, and the sample identification information D1 for specifying the print sample is inputted. Based on the inputted sample identification information D1, sample image data is selected, and the selected sample image data and image data and/or character data based on the order are merged to create a print according to the specified sample. This procedure allows a user to directly check full-sized samples of various dimensions before placing an order. This permits wide-ranging user requirements to be satisfied.

The first sample identification information D2 for specifying the first sample, and first sample image data are memorized; alternatively, the second sample identification information D3 for specifying the second sample, and second sample image data are memorized. The sample image data selected on the basis of the specified first and second sample identification information D2 and D3, and ordered image data and/or character data are merged with each other, and a print is created according to the specified sample. This procedure allows a greater variety of images to be created, and permits wide-ranging user requirements to be satisfied.

Operating section 11 is provided with information inputting means 12. Information inputting means 12 is constituted by a touch panel, etc., so as to output a push-down signal generated in information inputting means 12 to control section 7 as an inputting signal. Incidentally, it is also applicable that operating section 11 is provided with a keyboard, a mouse, etc. Further, CRT 8 displays image information, etc., according to the display controlling signals inputted from control section 7.

Communicating section 33 (output) transmits the output image signals, representing the captured image and processed by the image-processing method embodied in the present invention, and its corresponding order information to a separate computer located within the site in which image-recording apparatus 1 is installed and/or to a computer located in a remote site through Internet, etc.

As shown in FIG. 2, the image recording apparatus 1 is provided with: an input section for capturing the digital image data of various types and image information obtained by dividing the image document and measuring a property of light; an image processing section; an image outputting section for displaying or printing out the processed image on the image recording medium; and a communications section (output) for sending the image data and accompanying order information to another computer in the facilities through a communications line or a remote computer through Internet, etc.

Internal Configuration of Image Processing Section 70

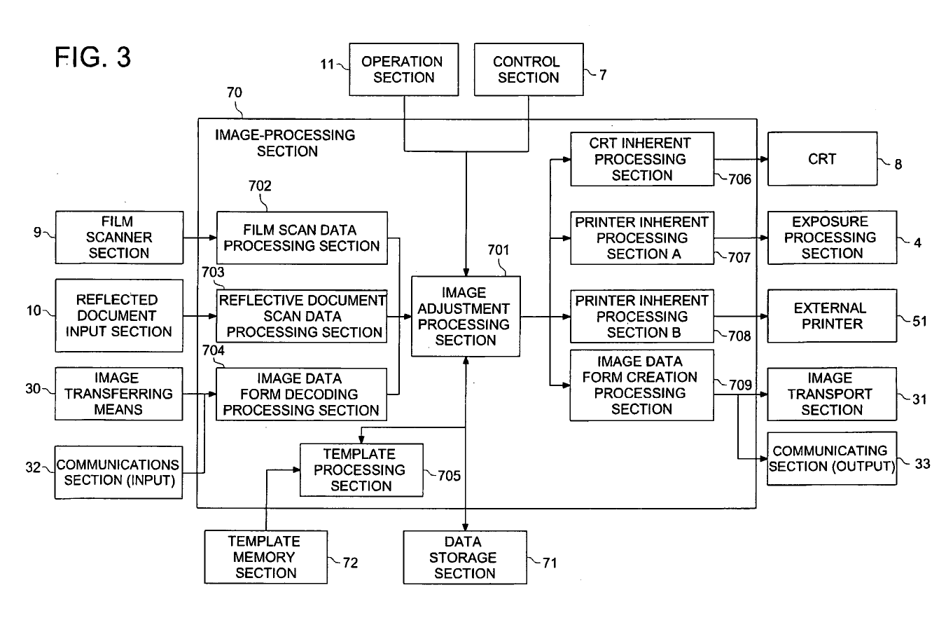

FIG. 3 shows a block diagram of the functional configuration of image processing section 70. Referring to FIG. 3, the configuration of image processing section 70 will be detailed in the following.

As shown in FIG. 3, image processing section 70 is provided with image adjustment processing section 701, film scan data processing section 702, reflective document scan data processing section 703, image data form decoding processing section 704, template processing section 705, CRT inherent processing section 706, printer inherent processing section A 707, printer inherent processing section B 708, image data form creation processing section 709.

The film scan data processing section 702 applies various kinds of processing operations to the image data inputted from film scanner section 9, such as a calibrating operation inherent to film scanner section 9, a negative-to-positive reversal processing (in the case of the negative original), an operation for removing contamination and scars, a contrast adjusting operation, an operation for eliminating granular noise, a sharpness enhancement, etc. Then, film scan data processing section 702 outputs the processed image data to image adjustment processing section 701, as well as the information pertaining to the film size, the classification of negative or positive, the major subject optically or magnetically recorded on a film, the image-capturing conditions (for instance, contents of the information recorded in APS), etc.

The reflective document scan data processing section 703 applies various kinds of processing operations to the image data inputted from reflective document input apparatus 10, such as a calibrating operation inherent to reflective document input apparatus 10, a negative-to-positive reversal processing (in the case of the negative original), an operation for removing contamination and scars, a contrast adjusting operation, an operation for eliminating noise, a sharpness enhancement, etc. to the image data inputted from and then outputs the processed image data to image adjustment processing section 701.

The image data form decoding processing section 704 applies a processing of decompression of the compressed symbol, a conversion of color data representation method, etc., to the image data inputted from image transfer section 30a and/or communications section (input) 32, as needed, according to the format of the inputted image data, and converts the image data into the format suited for computation in image processing section 70. Then, the image data form decoding processing section 704 outputs the processed data, to the image adjustment processing section 701. When the size of the output image is designated by any one of operation section 11, communications section (input) 32 and image transfer section 30, the image data form decoding processing section 704 detects the designated information, and outputs it to the image adjustment processing section 701. Information pertaining to the size of the output image designated by image transfer section 30 is embedded in the header information and the tag information acquired by image transfer section 30.

Based on the instruction command sent from operation section 11 or control section 7, the image adjustment processing section 701 applies various kinds of optimization processing, including a photographed scene estimation processing “A” detailed later, to the image data received from film scanner section 9, reflective document input apparatus 10, image transfer section 30, communications section (input) 32 and template processing section 705, so as to create output digital image data optimized for viewing a reproduced image on an output medium, and then, outputs the output digital image data to CRT inherent processing section 706, printer inherent processing section A 707, printer inherent processing section B 708, image data form creation processing section 709 and data accumulation section 71.

In the optimization processing, when it is premised that the image is displayed on the CRT displaying monitor based on, for instance, the sRGB standard, the image data is processed so as to acquire an optimum color reproduction within the color space specified by the sRGB standard. While, when it is premised that the image is outputted onto a silver-halide photosensitive paper, the image data is processed so as to acquire an optimum color reproduction within the color space specified by the silver-halide photosensitive paper. Further, other than the color space compression processing mentioned in the above, a gradation compression processing from 16 bits to 8 bits, a processing for reducing a number of output pixels, a processing for corresponding to output characteristics (LUT) of an output device to be employed, etc. are included in the optimization processing. Still further, it is needless to say that an operation for suppressing noise, a sharpness enhancement, a gray-balance adjustment, a chroma saturation adjustment, a dodging operation, etc. are also applied to the image data.

Based on the instruction command sent from image adjustment processing section 701, template processing section 705 reads the predetermined image data (template image data) from template storage 72 so as to conduct a template processing for synthesizing the image data, being as an image-processing object, with the template image data, and then, outputs the synthesized image data to image adjustment processing section 701.

The CRT inherent processing section 706 applies processing operations for changing the number of pixels and color matching, etc. to the image data inputted from image adjustment processing section 701, as needed, and outputs the output image data of displaying use, which are synthesized with information such as control information, etc. to be displayed on the screen, to CRT 8.

The printer inherent processing section A 707 conducts the calibration processing inherent to the printer and processing operations of color matching and changing the number of pixels, etc. as needed, and outputs the processed image data to exposure processing section 4.

When external printer 51, such as a large-sized inkjet printer, etc., is connectable to image recording apparatus 1 embodied in the present invention, printer inherent processing section B 708 is provided for every printer to be connected. The printer inherent processing section B 708 conducts the calibration processing inherent to the printer and processing operations of color matching and changing the number of pixels, etc. as needed, and outputs the processed image data to external printer 51.

The image data form creation processing section 709 applies a data-format conversion processing to the image data inputted from image adjustment processing section 701, as needed, so as to convert the data-format of the image data to one of various kinds of general-purpose image formants represented by JPEG, TIFF and Exif, and outputs the processed image data to image transport section 31 and communications section (output) 33.

Incidentally, the divided blocks of film scan data processing section 702, reflective document scan data processing section 703, image data form decoding processing section 704, image adjustment processing section 701, CRT inherent processing section 706, printer inherent processing section A 707, printer inherent processing section B 708 and image data form creation processing section 709, as shown in FIG. 3, are provided to assist understanding of the functions of image processing section 70. Therefore, each of divided blocks is not necessary functioned as a physically independent device. For instance, it is also applicable that each of divided blocks is functioned as one categorized processing of software executed by a single computer.

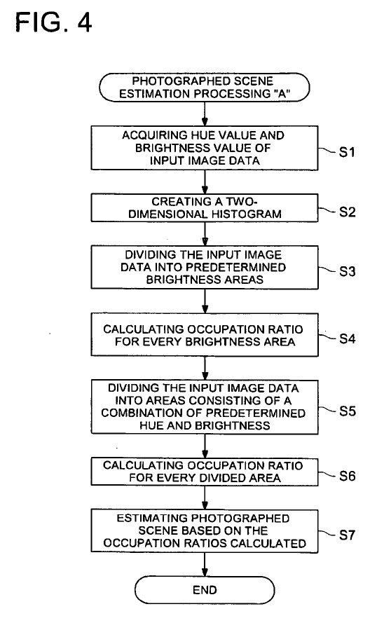

Next, the operations of the present invention will be detailed in the following. FIG. 4 shows a flowchart of the photographed scene estimation processing “A” conducted by image adjustment processing section 701. The photographed scene estimation processing “A” is conducted as a software processing executed by a computer, based on a photographed scene estimation A-program stored in a storage section, such as ROM, etc., (not shown in the drawings), and is commenced by inputting the image data into image adjustment processing section 701 from any one of film scan data processing section 702, reflective document scan data processing section 703 and image data form decoding processing section 704. Further, the photographed scene estimation processing “A” is performed by the data acquiring means, the brightness area dividing means, the HV dividing means, the brightness-area occupation ratio calculating means, the HV occupation ratio calculating means, the photographed scene estimating means and the two-dimensional histogram creating means, which are embodied in the present invention described in Items 23, 27, 45, 49, 35, 57.

When the image data is inputted from any one of film scan data processing section 702, reflective document scan data processing section 703 and image data form decoding processing section 704, a hue value and a brightness value of every pixel included in the inputted image data are acquired by converting the RGB color specification system of the inputted image data to another color specification system, such as L*a*b*, HSV, etc., and then, stored in the RAM (not shown in the drawings) (Step S1).

A concrete example of equations, for converting RGB values of each pixel included in the inputted image data to the hue value, the brightness value and the saturation value, will be shown in the following.

At first, with respect to examples of acquiring the hue value, the brightness value and the saturation value by converting the RGB color specification system to HSV color specification system, a concrete example employing program codes (C Language) will be detailed in the following, citing them in Eq. 1. Hereinafter, this conversion program is denoted as the “HSV conversion program”. In HSV color specification system, which was devised on the basis of the color specification system proposed by Munsell, a color is represented by three elemental attributes, namely, hue, saturation and brightness (or value).

Hereinafter, values of digital image data, serving as the inputted image data, are defined as InR, InG, InB. Further, calculated values of hue, saturation and brightness are defined as OutH, OutS, OutV, respectively. The scale of OutH is set at 0-360, while the unit of OutV is set at 0-255.

```
<Eq. 1>
  RGBtoHSV (RGB_Color) |
    Int max. min. r. g. b. d. rt. gt. Bt. OutH. OutS. OutV;
    r=InR
    g=InG
    b=InB
    max=(r> g) ? (r> b?r:b) : (g> b?g:b);
    min=(r< g) ? (r< b?r:b) : (g< b?g:b);
    d=max−min;
    OutV=max;
    If (max!=0) OutS=d×255/max; else OutS=0;
    If (OutS==0) |
      OutH=0;
    | else |
      rt=max−r×60/d;
      gt=max−g×60/d;
      bt=max−b×60/d;
      If (r==max) OutH=bt−gt; else
      If (g==max) OutH=120+rt−bt; else OutH=240+gt−rt;
      If (OutH< 0) OutH+=360;
    |
|
```

Other than the HVS, anyone, such as the L*a*b*, the L*u*v*, the Hunter L*a*b*, the YCC, the YIQ, etc., can be employed as the color specification system. In the present invention, the HSV color specification system from which the hue and brightness values can be directly acquired, is mainly employed.

As a reference example other than the HSV, an example of employing the L*a*b* will be detailed in the following. The L*a*b* color specification system (CIE1976) is one of the uniform color specification systems established by CIE (INTERNATIONAL COMMISSION ON ILLUMINATION) in 1976. The following <Eq. 2> specified by IEC1966-2-1 and <Eq. 3> specified by JISZ8729 are employed for deriving the L*a*b values from the RGB values. Then, the following <Eq. 4> is employed for deriving hue value (H′) and brightness value (S′) from the acquired L*a*b* values. However, hue value (H′) and brightness value (S′) derived by the above-mentioned procedure are different from the other hue value (H) and brightness value (S) of the aforementioned HSV color specification system.

$$\begin{matrix}{R}_{sRGB}^{′} = {R}_{sRGB ( 8 )} / 255 \\ {G}_{sRGB}^{′} = {G}_{sRGB ( 8 )} / 255 \\ {B}_{sRGB}^{′} = {B}_{sRGB ( 8 )} / 255 \\ {sRGB}^{′} > 0.03928 \\ {R}_{sRGB} = {( ( {R}_{sRGB}^{′} + 0.055 ) / 1.055 )}^{2.4} \\ {G}_{sRGB} = {( ( {G}_{sRGB}^{′} + 0.055 ) / 1.055 )}^{2.4} \\ {B}_{sRGB} = {( ( {B}_{sRGB}^{′} + 0.055 ) / 1.055 )}^{2.4} \\ \\ {sRGB}^{′} ⇐ 0.03928 \\ {R}_{sRGB} = {R}_{sRGB}^{′} / 12.92 \\ {G}_{sRGB} = {G}_{sRGB}^{′} / 12.92 \\ {B}_{sRGB} = {B}_{sRGB}^{′} / 12.92 \\ \\ ◆RGB \to CIE XYZ CCIR709 ( {D}_{65} ) \\ [ \begin{matrix}X \\ Y \\ Z\end{matrix} ] = [ \begin{matrix}0.4124 & 0.3576 & 0.1805 \\ 0.2126 & 0.7152 & 0.0722 \\ 0.0193 & 0.1192 & 0.9505\end{matrix} ] [ \begin{matrix}{R}_{sRGB} \\ {G}_{sRGB} \\ {B}_{sRGB}\end{matrix} ]\end{matrix} \qquad < Eq . 2 >$$

♦CIE XYZ→CIE L*a*b*
(when Y/Yn>0.008856)L*=116×(Y/Yn)^{(1/3)}−16
(when Y/Yn≦0.008856)L*=903.29×Y/Yn
a*=500×(f(X/Xn)−f(Y/Yn))
b*=200×(f(Y/Yn)−f(Z/Zn))
Yn=1(D₆₅)
(when Y/Yn>0.008856)f(t)=t^{(1/3)}
(when Y/Yn≦0.008856)f(t)=7.787×t+16/116 <Eq. 3>
H′=tan θ(b*/a*)
S′=\sqrt{(a*)²+(b*)²} <Eq. 4>

The <Eq. 2> shown in the above indicates that the equations included in <Eq. 2> convert the inputted 8-bits image data (R_{sRGB(8)}, G_{sRGB(8)}, B_{sRGB(8)}) to tristimulus values (X, Y, Z) of the color matching functions. Incidentally, the color matching functions are such functions that indicate the distribution of spectral sensitivities of the human eyes. Further, the suffix of sRGB shown in the inputted 8-bits image data (R_{sRGB(8)}, G_{sRGB(8)}, B_{sRGB(8)}) indicates that the RGB values of the inputted image data conform to the sRGB standard, and the suffix of (8) indicates that the inputted image data are 8-bits image data (0-255).

Further, <Eq. 3> shown in the above indicates that the equations included in <Eq. 3> convert the tristimulus values (X, Y, Z) to the L*a*b*. Xn, Yn and Zn shown in <Eq. 3> respectively indicate X, Y and Z of the standard white board, and D₆₅ indicates tristimulus values when the standard white board is illuminated by the light having a color temperature of 6500K. In <Eq. 3> shown in the above, there are established Xn=0.95, Yn=1.00 and Zn=1.09.

When the hue value and the brightness value of every pixel included in the inputted image data are acquired in step S1, a two-dimensional histogram, which indicates a cumulative frequency distribution of the pixels, is created in the coordinate plane having an x-axis as the hue value (H) and a y-axis as the brightness value (V) (step S2).

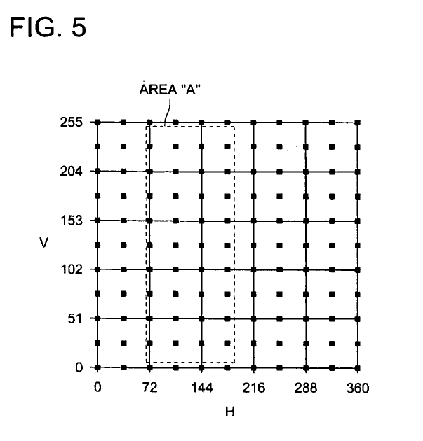

FIG. 5 shows an example of the two-dimensional histogram. In the two-dimensional histogram shown in FIG. 5, lattice points having values of the cumulative frequency distribution of the pixels are plotted in the coordinate plane having the x-axis as the hue value (H) and the y-axis as the brightness value (V). The lattice points located at the edge of the coordinate plane retain cumulative frequency of pixels distributing in such a range that the hue value (H) is 18, while the brightness value (V) is about 13. The other lattice points retain cumulative frequency of pixels distributing in such a range that the hue value (H) is 36, while the brightness value (V) is about 25. Area “A” indicates a green hue area having a hue value (H) in a range of 70-184.

Successively, the inputted image data are divided into the predetermined brightness areas, based on the two-dimensional histogram created in the above (step S3).

Concretely speaking, by dividing the created two-dimensional histogram into at least two planes with a border of at least one brightness value defined in advance, the inputted image data are divided into the predetermined brightness areas. In the present invention, it is desirable that the inputted image data are divided into three brightness areas by employing at least two brightness values. Further, it is also desirable that the brightness values for the border are established at 85 and 170 as values calculated by the aforementioned HSV conversion program. In the present embodiment, the two-dimensional histogram (namely, the inputted image data) is divided into three brightness areas by employing two brightness values of 85 and 170. According to this operation, it becomes possible to divide the two-dimensional histogram (namely, the inputted image data) into a shadow area (brightness value: 0-84), an intermediate area (brightness value: 85-169) and a highlighted area (brightness value: 170-255).

When the inputted image data are divided into the predetermined brightness areas, by dividing each of the sigma values of cumulative frequency distributions of the divided brightness areas by the total number of pixels included in the inputted image data with respect to each of the three brightness areas divided in the above, a ratio of each of the divided brightness areas and the total image area represented by the inputted image data, namely, an occupation ratio for every brightness area is calculated (step S4).

Successively, based on the two-dimensional histogram created in the above, the inputted image data are divided into areas having combinations of predetermined hue and brightness (step S5).

Concretely speaking, by dividing the created two-dimensional histogram into at least four planes with borders of at least one hue value and one brightness value defined in advance, the inputted image data are divided into the areas having combinations of predetermined hue and brightness. In the present invention, it is desirable that the inputted image data are divided into six areas by employing at least one hue value and two brightness values. Further, it is also desirable that the hue value for the borders is established at 70 as a value calculated by the aforementioned HSV conversion program. Still further, it is also desirable that the brightness values for the borders are established at 85 and 170 as values calculated by the aforementioned HSV conversion program. In the present embodiment, the two-dimensional histogram (namely, the inputted image data) is divided into the areas by employing at least one hue value of 70 and two brightness values of 85 and 170. According to this operation, it becomes possible to divide the two-dimensional histogram (namely, the inputted image data) into at least three areas of a flesh-color shadow area (hue value: 0-69, brightness value: 0-84), a flesh-color intermediate area (hue value: 0-69, brightness value: 85-169) and a flesh-color highlighted area (hue value: 0-69, brightness value: 170-255).

When the inputted image data are divided into the areas having combinations of predetermined hue and brightness, by dividing each of the sigma values of cumulative frequency distributions of the divided areas by the total number of pixels included in the inputted image data, a ratio of each of the divided areas and the total image area represented by the inputted image data, namely, an occupation ratio for every area is calculated (step S6).

Successively, based on the occupation ratio found in step S4 and S6, a photographed scene represented by the inputted image data is estimated (step S7). Concretely speaking, it is estimated whether the photographed scene was captured under the backlight condition or the strobe lighting condition, based on occupation ratios of shadow, intermediate and highlighted areas, and those of flesh-color shadow, flesh-color intermediate and flesh-color highlighted areas, and then, the photographed scene estimation processing “A” is finalized. As an estimation method, for instance, it is possible to estimate the photographed scene on the basis of a definition table stored in ROM, etc. As shown in <Definition 1>, the definition table includes definitions for correlated relationships between the photographed scene, and first magnitude relationships of the occupation ratios of shadow, intermediate and highlighted areas, and second magnitude relationships of the occupation ratios of flesh-color shadow, flesh-color intermediate and flesh-color highlighted areas.

Definition 1

Occupation ratio of shadow area: Rs
Occupation ratio of intermediate area: Rm
Occupation ratio of highlighted area: Rh
Occupation ratio of flesh-color shadow area: SkRs
Occupation ratio of flesh-color intermediate area: SkRm
Occupation ratio of flesh-color highlighted area: SkRh
Scene under backlight:
   Rs>Rm, Rh>Rm,
   SkRs>SkRm>SkRh
Scene under strobe lighting:
   Rh>Rs, Rh>Rm,
   SkRh>SkRm>SkRs
Normal scene: other than the above

The abovementioned definitions are derived from an empirical rule in regard to the magnitude relationships between shadow, intermediate and highlighted areas in the flesh-color hue area, in addition to those between shadow, intermediate and highlighted areas, for each of the scene under backlight condition and the scene under strobe lighting condition. Incidentally, the abovementioned empirical rule is such that, since the image-capturing operation of the scene under backlight condition is conducted under the condition that the sunlight, serving as a photographing light source, is positioned at a back of the subject, the flesh-color hue area of the subject is apt to deviate toward a low brightness area, while, in the image-capturing operation of the scene under strobe lighting condition, since the strobe light is directly irradiated onto the subject, the flesh-color hue area of the subject is apt to deviate toward a high brightness area. By employing the definitions mentioned in the above, it becomes possible to obtain a high-accurate estimation result, compared to the conventional method in which the photographed scene is estimated by employing merely the magnitude relationships between shadow, intermediate and highlighted areas, for each of the scene under backlight condition and the scene under strobe lighting condition.

Next, an example of employing the estimation result of the photographed scene estimation processing “A” for the gradation conversion processing will be detailed in the following.

Incidentally, an average brightness value of the overall image area is generally employed as an index for determining a target value after the gradation conversion processing, which is required at the time of conducting the gradation conversion processing. In the scene captured under backlight condition, the scene captured under strobe lighting condition, etc., however, bright and dark areas are mingled with each other, and the brightness of the face area, serving as an important subject in the image, deviates toward either the bright area or the dark area. Accordingly, in regard to the gradation conversion processing for the scene captured under backlight condition or the scene captured under strobe lighting condition, it would be an ideal practice to adjust the brightness of the face area so as to correct it to an appropriate value by employing an average brightness value of the face area rather than employing the average brightness value of the overall image area. In real photographing operations, since differences between bright and dark areas would variably differ from each other, it is desirable to adjust a weighted ratio of the brightness of the face area (hereinafter, referred to as a face-area contribution ratio).

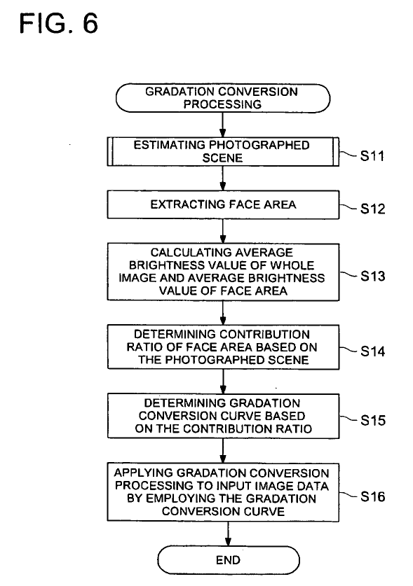

Accordingly, in the present embodiment, the gradation conversion processing, which takes a degree of difference between the face area and the overall image area into account, is conducted by using a result of the photographed scene estimation processing. FIG. 6 shows a flowchart of the gradation conversion processing performed by image adjustment processing section 701. This gradation conversion processing is conducted as a software processing executed by a computer, based on a gradation conversion program stored in a storage section, such as ROM, etc., (not shown in the drawings), and is commenced by inputting the image data into image adjustment processing section 701 from any one of film scan data processing section 702, reflective document scan data processing section 703 and image data form decoding processing section 704. Further, the gradation conversion processing is performed by the face area extracting means, the contribution ratio determining means and the gradation conversion processing means, which are embodied in the present invention described in Items 27-30, 23, 49-52.

Initially, the estimating operation of the photographed scene is conducted (step S11). In step S11, the photographed scene estimation processing, described in the foregoing by referring to FIG. 4, is conducted to estimate the photographed scene as any one of the scene captured under backlight condition, the scene captured under strobe lighting condition and the normal scene.

Successively, the face area is extracted from the inputted image data (step S12). Although there have been well-known various kinds of methods for extracting the face area, it is desirable in the present invention to create the two-dimensional histogram having the x-axis as the hue value (H) and the y-axis as the brightness value (V) so as to extract the pixels, distributed in the flesh-color area constituted by combinations of predetermined hue and brightness values, as the face area. It is also desirable that, when employing the two-dimensional histogram, the hue values calculated by the HSV conversion program are in a range of 0-50, while the brightness values calculated by the HSV conversion program are in a range of 10-120.

Incidentally, it is desirable that, in addition to the abovementioned method for extracting the flesh-color area, another image processing for extracting the face area is separately applied to the inputted image data in order to improve the accuracy of the extracting operation. Anyone of the processing methods applicable as public knowledge could be employed for the image processing for extracting the face area. The “simple area expansion method” can be cited as an example of the processing methods applicable as public knowledge mentioned in the above. According to the “simple area expanding method”, when a specific pixel (a flesh-color pixel), which falls under the definition of flesh-color, is discretely extracted, differences between the flesh-color pixel and the pixels located in the vicinity of it are found. Then, when the differences found in the above is smaller than a predetermined threshold value, the area including the flesh-color pixel is determined as the face area, and then, by gradually expanding the face area according to the abovementioned procedure, the whole face area can be extracted. Alternatively, it is also possible to extract the face area from the flesh-color area by using a learning function executed by a neural network.

When the extraction of the face area is completed, the average brightness value of the extracted face area and that of the overall image area are calculated (step S13). Further, the face-area contribution ratio is determined on the basis of the photographed scene estimated in step S11 (step S14). Based on the empirical rule, the face-area contribution ratios, corresponding to various kinds of the photographed scenes, are established in advance, for instance, as shown in the following <Definition 2>. Since the relationships between the photographed scenes and the face-area contribution ratios are established as a table stored in ROM, etc., the face-area contribution ratio based on the photographed scene is determined by referring to this table.

Definition 2

Scene under backlight condition=100 (%)
Scene under half-backlight condition=50 (%)
Scene under strobe lighting condition=100 (%)
Normal scene=30 (%)

With respect to the scene captured under the backlight condition, it is desirable to adjust the face-area contribution ratio, corresponding to the average brightness value of the face area or a brightness deviation amount for the overall image area, detailed later. In the abovementioned example, by setting the threshold level for the average brightness value of the face area, the degree of the scene captured under the backlight condition is divided into two steps as a result of determining whether or not the average brightness value exceeds the threshold level. However, it is also applicable that the degree of the scene captured under the backlight condition is divided into more finely divided steps.

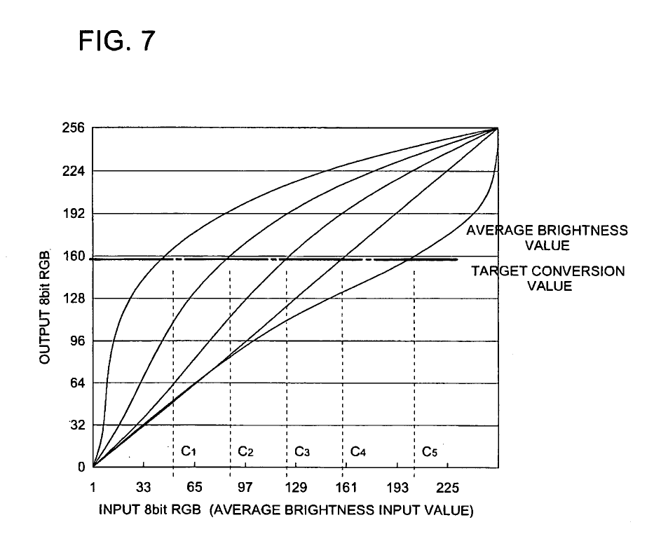

Successively, the gradation conversion curve to be applied to the inputted image data is determined on the basis of the face-area contribution ratio determined by the foregoing procedure (step S15). Concretely speaking, average brightness input values to be employed for the gradation conversion processing are calculated on the basis of the face-area contribution ratio, and then, as shown in FIG. 7, the gradation conversion curve is determined so as to convert the average brightness input values to a conversion target value of average brightness value. The average brightness input value (c) is calculated by employing equation 1 shown as follow.
c=a×(1−(Rsk×0.01))+(b×Rsk×0.01) <Equation 1>
where
   a: average brightness value of overall image area
   b: average brightness value of face area
   c: average brightness input value
   Rsk: face-area contribution ratio.

In FIG. 7, as for the scene captured under the backlight condition, the average brightness input values become C1 and C2, and the gradation conversion curves are determined so as to make the output values much bright. As for the normal scene, the average brightness input value becomes C3, and the gradation conversion curve is determined so as to make the output value slightly bright. As for the scene captured under the strobe lighting condition, the average brightness input values become C4 and C5, and the gradation conversion curves are determined so as to make the output values equivalent to or slightly lower than the input values.

It is possible to determine the gradation conversion curve by changing the old gradation conversion curve to new one created on the basis of the average brightness input values calculated by the foregoing procedure, every time when new image data are inputted. Alternatively, it is also possible to determine the gradation conversion curve by selecting a suitable one out of a plurality of gradation conversion curves, prepared in advance, corresponding to the average brightness input values.

When the adjustment of the gradation conversion curve is completed, the gradation conversion processing is applied to the inputted image data by employing the adjusted gradation conversion curve (step S16), and then, the whole process of the gradation conversion processing is finalized.

As described in the above, according to image-recording apparatus 1, the hue value and the brightness value of the inputted image data are acquired to create the two-dimensional histogram, which indicates the cumulative frequency distribution of the pixels in the coordinate plane having the x-axis as the hue value (H) and the y-axis as the brightness value (V). Then, the two-dimensional histogram is divided into the predetermined brightness areas so as to calculate the occupation ratios of the shadow area, the intermediate area and the highlighted area, respectively, and further, the two-dimensional histogram is divided into the areas having the combinations of predetermined hue and brightness so as to calculate the other occupation ratios of the flesh-color shadow area, the flesh-color intermediate area and the flesh-color highlighted area, respectively. Finally, the photographed scene is estimated on the basis of the magnitude relationships between the occupation ratios of the shadow area, the intermediate area and the highlighted area, and the other magnitude relationships between the other occupation ratios of the flesh-color shadow area, the flesh-color intermediate area and the flesh-color highlighted area.

Accordingly, since the empirical rule with respect to the flesh-color area is added to the magnitude relationships between the occupation ratios of the shadow area, the intermediate area and the highlighted area when estimating whether the photographed scene is either the scene captured under backlight condition or the scene captured under strobe lighting condition, it becomes possible to improve an accuracy of the estimation result of the photographed scene, compared to the conventional method.

Further, according to image-recording apparatus 1, since the gradation processing includes the steps of: extracting the face area of the inputted image data after completing the estimation processing of the photographed scene as aforementioned; determining the contribution ratio of the face area based on the photographed scene estimated in the above; determining the gradation conversion curve based on the contribution ratio determined in the above; and applying the gradation conversion processing to the inputted image data by employing the gradation conversion curve determined in the above, it becomes possible to apply the appropriate gradation processing.

### Second Embodiment

Next, referring to the drawings, the second embodiment of the present invention will be detailed in the following.

Incidentally, the configuration of the image-recording apparatus 1 for the second embodiment is the same as that shown in FIG. 1. Accordingly, the explanations for it will be omitted.

The operations performed in the second embodiment will be detailed in the following.

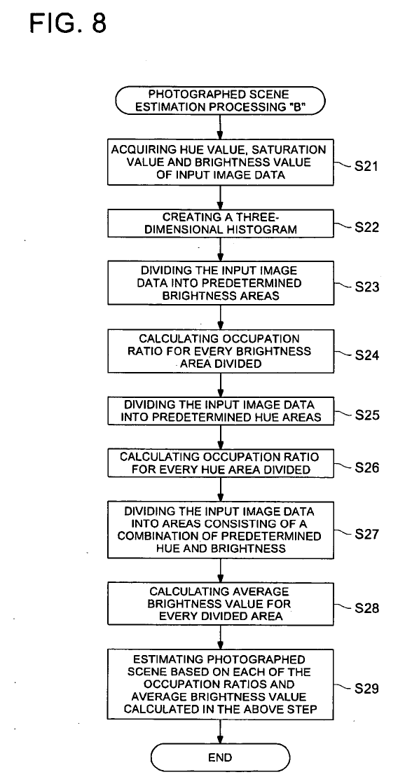

FIG. 8 shows a flowchart of the photographed scene estimation processing “B” conducted by image adjustment processing section 701. The photographed scene estimation processing “B” is conducted as a software processing executed by a computer, based on a photographed scene estimation B-program stored in a storage section, such as ROM, etc., (not shown in the drawings), and is commenced by inputting the image data into image adjustment processing section 701 from any one of film scan data processing section 702, reflective document scan data processing section 703 and image data form decoding processing section 704. Further, the photographed scene estimation processing “B” is conducted by the data acquiring means, the brightness area dividing means, the hue area dividing means, the HS dividing means, the brightness-area occupation ratio calculating means, the hue-area occupation ratio calculating means, the average brightness-value calculating means, the photographed scene estimating means and the three-dimensional histogram creating means, which are embodied in the present invention described in Items 24, 26, 28, 30, 46, 48, 50, 52, 36, 38, 58, 59.

When the image data is inputted from any one of film scan data processing section 702, reflective document scan data processing section 703 and image data form decoding processing section 704, the hue value, the saturation value and the brightness value of every pixel included in the inputted image data are calculated by converting the RGB color specification system of the inputted image data to another color specification system, such as L*a*b*, HSV, etc., and then, stored in the RAM (not shown in the drawings) (Step S21). For instance, the arithmetic equations, such as <Eq. 1>, <Eq. 2>-<Eq. 4>, etc., described in the first embodiment, are employed for calculating the hue value, the saturation value and the brightness value from the RGB values of every pixel.

When the hue value, the saturation value and the brightness value of every pixel included in the inputted image data are acquired, a three-dimensional histogram, which indicates a cumulative frequency distribution of the pixels, is created in the coordinate space having an x-axis as the hue value (H), a y-axis as the saturation value (S) and a z-axis as the brightness value (V) (step. S22).

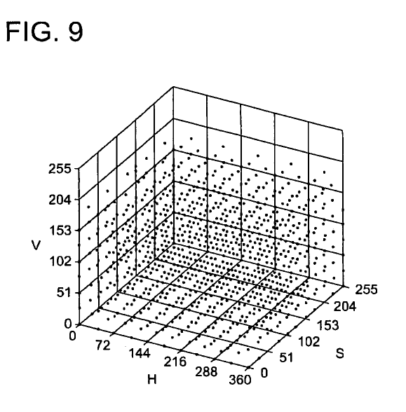

FIG. 9 shows an example of the three-dimensional histogram. In the three-dimensional histogram shown in FIG. 9, lattice points having values of the cumulative frequency distribution of the pixels are plotted in the coordinate space having the x-axis as the hue value (H), the y-axis as the saturation value (S) and the z-axis as the brightness value (V). The lattice points located at the surface of the coordinate space retain cumulative frequency of pixels distributing in such a range that the hue value (H) is 18, while both the saturation value (S) and the brightness value (V) are about 13. The other lattice points retain cumulative frequency of pixels distributing in such a range that the hue value (H) is 36, while both the saturation value (S) and the brightness value (V) are about 25.

Successively, the inputted image data are divided into the predetermined brightness areas, based on the three-dimensional histogram created in the above (step S23).

Concretely speaking, by dividing the created three-dimensional histogram into at least two spaces with a border of at least one brightness value defined in advance, the inputted image data are divided into the predetermined brightness areas. In the present invention, it is desirable that the inputted image data are divided into three spaces by employing at least two brightness values. Further, it is also desirable that the brightness values for the border are established at 85 and 170 as values calculated by the aforementioned HSV conversion program. In the present embodiment, the two-dimensional histogram (namely, the inputted image data) is divided into three brightness areas by employing two brightness values of 85 and 170. According to this operation, it becomes possible to divide the three-dimensional histogram (namely, the inputted image data) into a shadow area (brightness value: 0-84), an intermediate area (brightness value: 85-169) and a highlighted area (brightness value: 170-255).

When the inputted image data are divided into the predetermined brightness areas, by dividing each of the sigma values of cumulative frequency distributions of the divided brightness areas by the total number of pixels included in the inputted image data with respect to each of the three brightness areas divided in step S23, a ratio of each of the divided brightness areas and the total image area represented by the inputted image data, namely, an occupation ratio for every brightness area is calculated (step S24).

Successively, based on the three-dimensional histogram created in the above, the inputted image data are divided into predetermined hue areas (step S25).

Concretely speaking, by dividing the created three-dimensional histogram into at least two spaces with a border of at least one hue value defined in advance, the inputted image data are divided into the predetermined brightness areas. In the present invention, it is desirable that the inputted image data are divided into four spaces by employing at least three hue values. Further, it is also desirable that the hue values for the border are established at 70, 185 and 225 as values calculated by the aforementioned HSV conversion program. In the present embodiment, the three-dimensional histogram (namely, the inputted image data) is divided into four areas by employing the hue values of 70, 185 and 225. According to this operation, it becomes possible to divide the three-dimensional histogram (namely, the inputted image data) into three areas of a flesh-color hue area (hue value: 0-69), a green hue area (hue value: 70-184), a sky-blue hue area (hue value: 185-224) and a red hue area (hue value: 225-360).

When the inputted image data are divided into the predetermined hue areas, by dividing each of the sigma values of cumulative frequency distributions of the divided areas by the total number of pixels included in the inputted image data with respect to each of the hue areas divided in step S25, a ratio of each of the divided areas and the total image area represented by the inputted image data, namely, an occupation ratio for every area is calculated (step S26).

Further, by dividing the created three-dimensional histogram into at least four spaces with borders of at least one hue value and one saturation value defined in advance, the inputted image data are divided into the areas having combinations of predetermined hue and saturation. In the present invention, it is desirable that the inputted image data are divided into four spaces by employing at least one hue value and one saturation value. Further, it is also desirable that the hue value for the borders is established at 70 as a value calculated by the aforementioned HSV conversion program. Still further, it is also desirable that the saturation value for the borders is established at 128 as a value calculated by the aforementioned HSV conversion program. In the present embodiment, the three-dimensional histogram (namely, the inputted image data) is divided into the areas by employing the hue value of 70 and the saturation value of 128. According to this operation, it becomes possible to divide the three-dimensional histogram (namely, the inputted image data) into at least a flesh-color area (hue value: 0-69, saturation value: 0-128).

When the inputted image data are divided into the areas having combinations of predetermined hue and brightness, an average brightness value of the predetermined divided area, namely, the aforementioned flesh-color area, is calculated (step S28).

When the occupation ratio of every brightness area, the occupation ratio of every hue area and the average brightness value of the flesh-color area are calculated, a photographed scene is estimated on the basis of the calculated occupation ratio and the average brightness value (step S29). Concretely speaking, the brightness deviation amount of the flesh-color area is acquired by employing equation 2 shown as follow, and then, the photographed scene is estimated on the basis of magnitude relationships between the brightness deviation amount, the occupation ratio of every hue area and the occupation ratio of every brightness area. As an estimation method, for instance, it is possible to estimate the photographed scene on the basis of a definition table stored in advance in ROM, etc. As shown in <Definition 3>, the definition table includes definitions for correlated relationships between the photographed scene and the magnitude relationships of the brightness deviation amount, the occupation ratio of every hue area and the occupation ratio of every brightness area.
D=(A−B)/(C−D) <Equation 2>
where
   A: average brightness value of flesh-color area,
   B: maximum brightness value of overall image area,
   C: minimum brightness value of overall image area,
   D: brightness deviation amount of flesh-color area.
      Definition 3
D: brightness deviation amount of flesh-color area
Rs: occupation ratio of shadow area
Rh: occupation ratio of highlighted area
Rm: occupation ratio of intermediate area
D>0.6—scene captured under backlight condition
D<0.4, green hue area<15% and
   sky-blue hue area<30%—scene captured under strobe lighting condition
0.4≦D≦0.6, green hue area<15% and
   sky-blue hue area<30%, Rs≧20%—scene captured under strobe lighting condition
0.4≦D≦0.6, green hue area≧15% or
   sky-blue hue area≧30%, Rh>Rm—scene captured under backlight condition

Conditions other than the above categories fall into a normal scene.

The abovementioned equation 2 and Definition 3 take into account such an empirical rule that a backlight scene is apt to frequently occur in a landscape scene and therefore includes green trees and a blue sky. Further, the abovementioned equation 2 also takes into account such an empirical rule that a strobe lighting scene is apt to frequently occur in an indoor scene or a night scene and therefore scarcely includes green trees and a blue sky. Accordingly, it becomes possible to acquire a high-accurate estimation result of the photographed scene.

The photographed scene estimation processing “B”, mentioned in the above, can be employed for the estimation of the photographed scene in step S11 of the gradation conversion processing, which has been detailed in the aforementioned first embodiment referring to FIG. 6. In the gradation conversion processing shown in FIG. 6, by conducting the steps of: determining the contribution ratio of the face area based on the photographed scene estimated in the photographed scene estimation processing “B”; adjusting the gradation conversion curve based on the contribution ratio of the face area; and applying the gradation conversion processing to the inputted image data by employing the gradation conversion curve adjusted in the above, it becomes possible to apply the appropriate gradation processing.

As described in the above, according to image-recording apparatus 1, the hue value, the saturation value and the brightness value of the inputted image data are acquired to create the three-dimensional histogram, which indicates the cumulative frequency distribution of the pixels in the coordinate space having the x-axis as the hue value (H), the y-axis as the saturation value (S) and the z-axis as the brightness value (V). Then, by employing the three-dimensional histogram, the inputted image data are divided so as to calculate the occupation ratio for every brightness area, the occupation ratio for every hue area and the average brightness of the area having the combination of predetermined hue and saturation. Finally, the photographed scene is estimated on the basis of the occupation ratio and the average brightness value calculated in the above.

Accordingly, with respect to the estimation of the scene captured under backlight condition or the scene captured under strobe lighting condition, by adding the empirical rule in the flesh-color area and the other empirical rule in regard to a hue for every photographed scene to the magnitude relationships between the occupation ratios of the shadow area, the intermediate area and the highlighted area, it becomes possible to improve an accuracy of the estimation result of the photographed scene, compared to the conventional method.

Further, according to image-recording apparatus 1, since the gradation processing includes the steps of: extracting the face area of the inputted image data after completing the estimation processing of the photographed scene as aforementioned; determining the contribution ratio of the face area based on the photographed scene estimated in the above; adjusting the gradation conversion curve based on the contribution ratio of the face area; and applying the gradation conversion processing to the inputted image data by employing the gradation conversion curve adjusted in the above, it becomes possible to apply the appropriate gradation processing.

### Third Embodiment

Next, referring to the drawings, the third embodiment of the present invention will be detailed in the following.

Incidentally, the configuration of the image-recording apparatus 1 for the third embodiment is the same as that shown in FIG. 1. Accordingly, the explanations for it will be omitted.

The operations performed in the third embodiment will be detailed in the following.

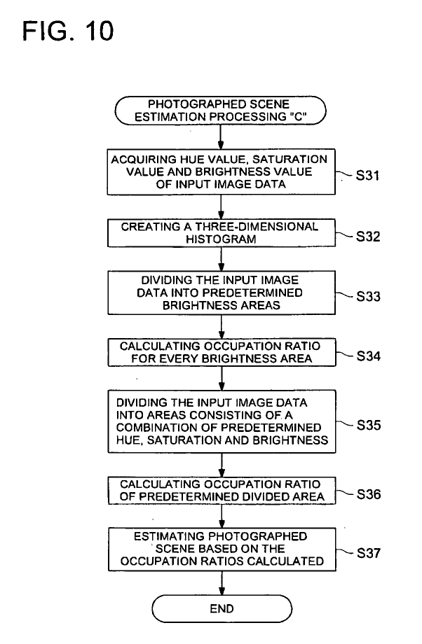

FIG. 10 shows a flowchart of the photographed scene estimation processing “C” conducted by image adjustment processing section 701. The photographed scene estimation processing “C” is conducted as a software processing executed by a computer, based on a photographed scene estimation C-program stored in a storage section, such as ROM, etc., (not shown in the drawings), and is commenced by inputting the image data into image adjustment processing section 701 from any one of film scan data processing section 702, reflective document scan data processing section 703 and image data form decoding processing section 704. Further, the photographed scene estimation processing “C” is performed by the data acquiring means, the brightness area dividing means, the HSV dividing means, the brightness-area occupation ratio calculating means, the HSV occupation ratio calculating means, the photographed scene estimating means and the three-dimensional histogram creating means, which are embodied in the present invention described in Items 25, 26, 29, 30, 47, 48, 51, 52, 37, 38, 59, 60.

When the image data is inputted from any one of film scan data processing section 702, reflective document scan data processing section 703 and image data form decoding processing section 704, the hue value, the saturation value and the brightness value of every pixel included in the inputted image data are calculated by converting the RGB color specification system of the inputted image data to another color specification system, such as L*a*b*, HSV, etc., and then, stored in the RAM (not shown in the drawings) (Step S31). For instance, the arithmetic equations, such as <Eq. 1>, <Eq. 2>-<Eq. 4>, etc., described in the first embodiment, are employed for calculating the hue value, the saturation value and the brightness value from the RGB values of every pixel.

When the hue value, the saturation value and the brightness value of every pixel included in the inputted image data are acquired, a three-dimensional histogram, which indicates a cumulative frequency distribution of the pixels, is created in the coordinate space having an x-axis as the hue value (H), a y-axis as the saturation value (S) and a z-axis as the brightness value (V) (step S32). The three-dimensional histogram created according to the above is substantially the same as, for instance, that described referring to FIG. 9.

Successively, the inputted image data are divided into the predetermined brightness areas, based on the three-dimensional histogram created in the above (step S33).

Concretely speaking, by dividing the created three-dimensional histogram into at least two spaces with a border of at least one brightness value defined in advance, the inputted image data are divided into the predetermined brightness areas. In the present invention, it is desirable that the inputted image data are divided into three spaces by employing at least two brightness values. Further, it is also desirable that the brightness values for the border are established at 85 and 170 as values calculated by the aforementioned HSV conversion program. In the present embodiment, the two-dimensional histogram (namely, the inputted image data) is divided into three brightness areas by employing two brightness values of 85 and 170. According to this operation, it becomes possible to divide the three-dimensional histogram (namely, the inputted image data) into a shadow area (brightness value: 0-84), an intermediate area (brightness value: 85-169) and a highlighted area (brightness value: 170-255).

When the inputted image data are divided into the predetermined brightness areas, by dividing each of the sigma values of cumulative frequency distributions of the divided areas by the total number of pixels included in the inputted image data with respect to each of the brightness areas divided in step S33, a ratio of each of the divided areas and the total image area represented by the inputted image data, namely, an occupation ratio for every brightness area is calculated (step S34).

Further, by dividing the created three-dimensional histogram into at least eight spaces with borders of at least one brightness value, one hue value and one brightness value defined in advance, the inputted image data are divided into the areas having predetermined hue, saturation and brightness (step S35). In the present invention, it is desirable that the inputted image data are divided by employing at least one hue value and two brightness values and one saturation value. Further, it is also desirable that the hue value for the borders is established at 70 as a value calculated by the aforementioned HSV conversion program. Still further, it is also desirable that the saturation value for the borders is established at 128 as a value calculated by the aforementioned HSV conversion program. Still further, it is also desirable that the brightness values for the borders are established at 85 and 170 as values calculated by the aforementioned HSV conversion program. In the present embodiment, the three-dimensional histogram (namely, the inputted image data) is divided into the areas by employing the hue value of 70, the saturation value of 128 and the brightness values of 85 and 170. According to this operation, it becomes possible to divide the three-dimensional histogram (namely, the inputted image data) into at least three areas of a flesh-color shadow area (hue value: 0-69, saturation value: 0-128, brightness value: 0-84), a flesh-color intermediate area (hue value: 0-69, saturation value: 0-128, brightness value: 85-169) and a flesh-color highlighted area (hue value: 0-69, saturation value: 0-128, brightness value: 170-255).

When the inputted image data are divided into the predetermined brightness areas, by dividing the sigma value of the cumulative frequency distribution of each area by the total number of pixels included in the inputted image data with respect to each of the predetermined areas divided in step S35, namely, with respect to the flesh-color shadow area, the flesh-color intermediate area and the flesh-color highlighted area, a ratio of each of the divided areas and the total image area represented by the inputted image data, namely, an occupation ratio for each of the flesh-color shadow area, the flesh-color intermediate area and the flesh-color highlighted area, is calculated (step S36).

When the occupation ratio of every brightness area and the occupation ratio of each of the predetermined areas divided in the above are calculated, a photographed scene is estimated on the basis of the calculated occupation ratios (step S37). Concretely speaking, based on the occupation ratios of the shadow, intermediate and highlighted areas and those of the flesh-color shadow, flesh-color intermediate and flesh-color highlighted areas, it is estimated whether the photographed scene is categorized in the scene captured under the backlight condition, the scene captured under the strobe lighting condition or the normal scene, and then, the photographed scene estimation processing “C” is finalized. As an estimation method, for instance, it is possible to estimate the photographed scene on the basis of a definition table stored in ROM, etc. As shown in <Definition 4>, the definition table includes definitions for correlated relationships between the photographed scene, and first magnitude relationships of the occupation ratios of shadow, intermediate and highlighted areas, and second magnitude relationships of the occupation ratios of flesh-color shadow, flesh-color intermediate and flesh-color highlighted areas.

Definition 4

Occupation ratio of shadow area: Rs
Occupation ratio of intermediate area: Rm
Occupation ratio of highlighted area: Rh
Occupation ratio of flesh-color shadow area: SkRs
Occupation ratio of flesh-color intermediate area: SkRm
Occupation ratio of flesh-color highlighted area: SkRh
Scene under backlight:
   Rs>Rm, Rh>Rm,
   SkRs>SkRm>SkRh
Scene under strobe lighting:
   Rh>Rs, Rh>Rm,
   SkRh>SkRm>SkRs
Normal scene: other than the above

The abovementioned definitions are derived from an empirical rule in regard to the magnitude relationships between shadow, intermediate and highlighted areas in the flesh-color hue area, in addition to those between shadow, intermediate and highlighted areas, for each of the scene under backlight condition and the scene under strobe lighting condition. Incidentally, the abovementioned empirical rule is such that, since the image-capturing operation of the scene under backlight condition is conducted under the condition that the sunlight, serving as a photographing light source, is positioned at a back of the subject, the flesh-color hue area of the subject is apt to deviate toward a low brightness area, while, in the image-capturing operation of the scene under strobe lighting condition, since the strobe light is directly irradiated onto the subject, the flesh-color hue area of the subject is apt to deviate toward a high brightness area. By employing the definitions mentioned in the above, it becomes possible to obtain a high-accurate estimation result, compared to the conventional method in which the photographed scene is estimated by employing merely the magnitude relationships between shadow, intermediate and highlighted areas, for each of the scene under backlight condition and the scene under strobe lighting condition.

The photographed scene estimation processing “C”, mentioned in the above, can be employed for the estimation of the photographed scene in step S11 of the gradation conversion processing, which has been detailed in the aforementioned first embodiment referring to FIG. 6. In the gradation conversion processing shown in FIG. 6, by conducting the steps of: determining the contribution ratio of the face area based on the photographed scene estimated in the photographed scene estimation processing “C”; adjusting the gradation conversion curve based on the contribution ratio of the face area; and applying the gradation conversion processing to the inputted image data by employing the gradation conversion curve adjusted in the above, it becomes possible to apply the appropriate gradation processing.

As described in the above, according to image-recording apparatus 1, the hue value, the saturation value and the brightness value of the inputted image data are acquired to create the three-dimensional histogram, which indicates the cumulative frequency distribution of the pixels in the coordinate space having the x-axis as the hue value (H), the y-axis as the saturation value (S) and the z-axis as the brightness value (V). Then, the inputted image data are divided by employing the three-dimensional histogram, so as to respectively calculate the occupation ratio for every divided-brightness area (such as, the shadow area, the intermediate area and highlighted area) and the other occupation ratio for every divided area having the combination of the predetermined hue, saturation and brightness (such as, the flesh-color shadow area, the flesh-color intermediate area and the flesh-color highlighted area). Finally, the photographed scene is estimated on the basis of the occupation ratios calculated in the above.

Accordingly, since the empirical rule with respect to the flesh-color area is added to the magnitude relationships between the occupation ratios of the shadow area when estimating whether the photographed scene is either the scene captured under backlight condition or the scene captured under strobe lighting condition, it becomes possible to improve an accuracy of the estimation result of the photographed scene, compared to the conventional method.

Further, according to image-recording apparatus 1, since the gradation processing includes the steps of: extracting the face area of the inputted image data after completing the estimation processing of the photographed scene as aforementioned; determining the contribution ratio of the face area based on the photographed scene estimated in the above; adjusting the gradation conversion curve based on the contribution ratio of the face area; and applying the gradation conversion processing to the inputted image data by employing the gradation conversion curve adjusted in the above, it becomes possible to apply the appropriate gradation processing.

Incidentally, it is possible to further improve the estimation accuracy of the photographed scene when a combination of the photographed scene estimation processing “B” and the photographed scene estimation processing “C”, both being detailed in the aforementioned second embodiment and the aforementioned third embodiment, is employed for processing the inputted image data. In other words, by executing the photographed scene estimation processing “B”, the occupation ratio for every brightness area, the occupation ratio for every hue area and the average brightness value of the area having the combination of predetermined hue and saturation (herein, the flesh-color area) are calculated with respect to the inputted image data, and at the same time, by executing the photographed scene estimation processing “C”, the occupation ratio of the area having the combination of predetermined hue, saturation and brightness (herein, the shadow area, the intermediate area and the highlighted area in the flesh-color area) are calculated with respect to the inputted image data. Then, the photographed scene is estimated on the basis of the occupation ratios and the average brightness value calculated in the above. According to this process, it becomes possible to further improve the estimation accuracy of the photographed scene. In addition, by employing the combination of the photographed scene estimation processing “B” and the photographed scene estimation processing “C” for the processing for estimating the photographed scene as shown in FIG. 6, it becomes possible to conduct a further appropriate gradation conversion processing.

In the foregoing, there have been detailed the first embodiment, the second embodiment and the second embodiment. It is desirable that the image data to be processed in such the embodiments would be scene-referred image data when the image data represent an image captured by a digital camera. The term of “scene-referred image data” means such an image data that signal intensities of each color channel based on the spectral sensitivity of the image-capturing device itself are already mapped on the standard color space, such as the RIMM RGB, the ERIMM RGB, etc., and in a state that the image-processing, for changing the contents of the image data to improve the effect at the time of viewing the image, such as the gradation conversion processing, the sharpness enhancement processing and the saturation enhancement processing, are omitted. Accordingly, it becomes possible to form an optimized output image based on the output-referred image data without loosing any information included in the originally-photographed image information, by conducting the steps of: inputting the scene-referred image data into image-recording apparatus 1; and converting the scene-referred image data to the output-referred image data by applying the optimization processing including the aforementioned photographed scene estimation processing and the gradation conversion processing to the scene-referred image data, so that the optimized output image can be acquired on an output medium (such as a CRT, a liquid-crystal display, a plasma display, a silver-halide photosensitive paper, an ink-jet paper, a thermal-printing paper, etc.) based on the output device information inputted from operating section 11 in image adjustment processing section 701.

Incidentally, the contents of the embodiments, described in the foregoing, merely indicate several examples suitable for the present invention. Accordingly, the scope of the present invention is not limited to the embodiments disclosed in the present specification.

For instance, although the image-recording apparatus, which provided with the function of recording the image after applying the image processing operations to the inputted image data, is exemplified in the explanation of the aforementioned embodiments, it is needless to say that the present invention can be implemented for an image-processing apparatus having a function of outputting an image to an image-recording apparatus.

Further, although either the two-dimensional histogram or the three-dimensional histogram is employed for dividing the inputted image data in the aforementioned embodiment, it is also applicable that the inputted image data are divided on the basis of the hue value, brightness value and saturation value acquired from the inputted image data without employing the two-dimensional histogram or the three-dimensional histogram. By employing either the two-dimensional histogram or the three-dimensional histogram, however, it becomes possible to improve the efficiency of the processing.

Other than the above, with respect to the details of the configuration and the operations of image-recording apparatus 1, the disclosed embodiments can be varied by a skilled person without departing from the spirit and scope of the invention.

1. An image processing method of obtaining captured image data of pixels corresponding to one image plane and outputting image data optimized for viewing on an outputting medium, comprising:
(1) a color specifying process of acquiring a hue value and a brightness value for every pixel of the captured image data;
(2) a brightness value distributing process of dividing a brightness region into plural brightness regions by a predetermined brightness value and distributing the pixels of the captured image data in accordance with the brightness value of each pixel into one of the plural brightness regions;
(3) a color specification value distributing process of dividing a two dimensional color specification region into plural color specification regions by predetermined hue and brightness values and distributing the pixels of the captured image data in accordance with the hue and brightness values of each pixel into one of the plural color specification regions;
(4) a brightness region occupation ratio calculating process of calculating a brightness region occupation ratio representing a occupation ratio of the distributed pixels of each brightness region to all pixels of the one image plane;
(5) a color specification region occupation ratio calculating process of calculating a color specification region occupation ratio representing a occupation ratio of the distributed pixels of each color specification region to all pixels of the one image plane; and
(6) a photographing scene estimating process of estimating a photographing scene of the captured image data on the basis of the calculated brightness region occupation ratio and the calculated color specification region occupation ratio.

2. The image processing method of claim 1, wherein the plural brightness regions comprises a shadow region defined by brightness values from 0 to 84 on the basis of the HSV color specification system, an intermediate region defined by brightness values from 85 to 169, and a highlight region defined by brightness values from 170 to 255, and the plural color specification regions comprises a flesh color shadow region defined by hue values from 0 to 69 and brightness values from 0 to 84 on the basis of the HSV color specification system, a flesh color medium region defined by hue values from 0 to 69 and brightness values from 85 to 169, and a flesh color highlight region defined by hue values from 0 to 69 and brightness values from 170 to 255.

3. The image processing method of claim 1, further comprising: a histogram producing process of producing a two dimensional histogram of the obtained hue and brightness values and the brightness value distributing process and the color specification value distributing process are conducted based on the two dimensional histogram.

4. The image processing method of claim 1, further comprising: a face region extracting process of extracting image data a face region from the captured image data, a contribution ratio determining process of determining a contribution ratio of the face region to a gradation converting process, and a gradation converting processing process of conducting a gradation converting process to the captured image data.

5. The image processing method of claim 4, wherein the color specifying process acquires a hue value, a brightness value and a saturation value for every pixel of the captured image data and the face region extracting process extracts a region defined by predetermined hue and saturation values as the face region.

6. The image processing method of claim 5, wherein the face region extracting process includes a histogram producing process of producing a two dimensional histogram of the obtained hue and saturation values and extracts the face region on the basis of the produced two dimensional histogram.

7. The image processing method of claim 5, wherein the region defined by the predetermined hue and saturation values is a region defined by hue values from 0 to 50 and saturation values from 10 to 120 on the basis of the HSV color specification system.

8. The image processing method of claim 1, wherein the color specifying process acquires a hue value, a brightness value and a saturation value for every pixel of the captured image data; the color specification value distributing process divides a three dimensional color specification space region into plural color specification space regions by predetermined hue, brightness and saturation values and distributing the pixels of the captured image data in accordance with the hue, brightness and saturation values of each pixel into one of the plural color specification space regions; the color specification region occupation ratio calculating process calculates a color specification space region occupation ratio representing a occupation ratio of the distributed pixels of each color specification space region to all pixels of the one image plane; and the photographing scene estimating process estimates a photographing scene of the captured image data on the basis of the calculated brightness region and color specification region occupation ratios.

9. The image processing method of claim 8, wherein the plural brightness regions comprises a shadow region defined by brightness values from 0 to 84 on the basis of the HSV color specification system, an intermediate region defined by brightness values from 85 to 169, and a highlight region defined by brightness values from 170 to 255, and the plural color specification space regions comprises a flesh color shadow space region defined by hue values from 0 to 69, saturation values from 0 to 128 and brightness values from 0 to 84 on the basis of the HSV color specification system, a flesh color medium space region defined by hue values from 0 to 69, saturation values from 0 to 128 and brightness values from 85 to 169, and a flesh color highlight space region defined by hue values from 0 to 69, saturation values from 0 to 128 and brightness values from 170 to 255.

10. The image processing method of claim 8, further comprising: a histogram producing process of producing a three dimensional histogram of the obtained hue, saturation and brightness values and the brightness value distributing process and the color specification value distributing process are conducted based on the three dimensional histogram.

11. The image processing method of claim 8, further comprising: a face region extracting process of extracting image data a face region from the captured image data, a contribution ratio determining process of determining a contribution ratio of the face region to a gradation converting process, and a gradation converting processing process of conducting a gradation converting process to the captured image data.

12. The image processing method of claim 8, wherein the color specifying process acquires a hue value, a brightness value and a saturation value for every pixel of the captured image data and the face region extracting process extracts a region defined by predetermined hue and saturation values as the face region.

13. The image processing method of claim 12, wherein the face region extracting process includes a histogram producing process of producing a two dimensional histogram of the obtained hue and saturation values and extracts the face region on the basis of the produced two dimensional histogram.

14. The image processing method of claim 12, wherein the region defined by the predetermined hue and saturation values is a region defined by hue values from 0 to 50 and saturation values from 10 to 120 on the basis of the HSV color specification system.

15. An image processing apparatus of obtaining captured image data of pixels corresponding to one image plane and outputting image data optimized for viewing on an outputting medium, comprising:
(1) a color specifying section for acquiring a hue value and a brightness value for every pixel of the captured image data;
(2) a brightness value distributing section for dividing a brightness region into plural brightness regions by a predetermined brightness value and distributing the pixels of the captured image data in accordance with the brightness value of each pixel into one of the plural brightness regions;
(3) a color specification value distributing section for dividing a two dimensional color specification region into plural color specification regions by predetermined hue and brightness values and distributing the pixels of the captured image data in accordance with the hue and brightness values of each pixel into one of the plural color specification regions;
(4) a brightness region occupation ratio calculating section for calculating a brightness region occupation ratio representing a occupation ratio of the distributed pixels of each brightness region to all pixels of the one image plane;
(5) a color specification region occupation ratio calculating section for calculating a color specification region occupation ratio representing a occupation ratio of the distributed pixels of each color specification region to all pixels of the one image plane; and
(6) a photographing scene estimating section for estimating a photographing scene of the captured image data on the basis of the calculated brightness region occupation ratio and the calculated color specification region occupation ratio.

16. The image processing apparatus of claim 15, wherein the plural brightness regions comprises a shadow region defined by brightness values from 0 to 84 on the basis of the HSV color specification system, an intermediate region defined by brightness values from 85 to 169, and a highlight region defined by brightness values from 170 to 255, and the plural color specification regions comprises a flesh color shadow region defined by hue values from 0 to 69 and brightness values from 0 to 84 on the basis of the HSV color specification system, a flesh color medium region defined by hue values from 0 to 69 and brightness values from 85 to 169, and a flesh color highlight region defined by hue values from 0 to 69 and brightness values from 170 to 255.

17. The image processing apparatus of claim 15, further comprising: a histogram producing section for producing a two dimensional histogram of the obtained hue and brightness values and the brightness value distributing section and the color specification value distributing section are conducted based on the two dimensional histogram.

18. The image processing apparatus of claim 15, further comprising: a face region extracting section for extracting image data a face region from the captured image data, a contribution ratio determining section for determining a contribution ratio of the face region to a gradation converting section, and a gradation converting processing section for conducting a gradation converting section to the captured image data.

19. The image processing apparatus of claim 18, wherein the color specifying section acquires a hue value, a brightness value and a saturation value for every pixel of the captured image data and the face region extracting section extracts a region defined by predetermined hue and saturation values as the face region.

20. The image processing apparatus of claim 19, wherein the face region extracting section includes a histogram producing section for producing a two dimensional histogram of the obtained hue and saturation values and extracts the face region on the basis of the produced two dimensional histogram.

21. The image processing apparatus of claim 19, wherein the region defined by the predetermined hue and saturation values is a region defined by hue values from 0 to 50 and saturation values from 10 to 120 on the basis of the HSV color specification system.

22. The image processing apparatus of claim 15, wherein the color specifying section acquires a hue value, a brightness value and a saturation value for every pixel of the captured image data; the color specification value distributing section divides a three dimensional color specification space region into plural color specification space regions by predetermined hue, brightness and saturation values and distributing the pixels of the captured image data in accordance with the hue, brightness and saturation values of each pixel into one of the plural color specification space regions; the color specification region occupation ratio calculating section calculates a color specification space region occupation ratio representing a occupation ratio of the distributed pixels of each color specification space region to all pixels of the one image plane; and the photographing scene estimating section estimates a photographing scene of the captured image data on the basis of the calculated brightness region and color specification region occupation ratios.

23. The image processing apparatus of claim 22, wherein the plural brightness regions comprises a shadow region defined by brightness values from 0 to 84 on the basis of the HSV color specification system, an intermediate region defined by brightness values from 85 to 169, and a highlight region defined by brightness values from 170 to 255, and the plural color specification space regions comprises a flesh color shadow space region defined by hue values from 0 to 69, saturation values from 0 to 128 and brightness values from 0 to 84 on the basis of the HSV color specification system, a flesh color medium space region defined by hue values from 0 to 69, saturation values from 0 to 128 and brightness values from 85 to 169, and a flesh color highlight space region defined by hue values from 0 to 69, saturation values from 0 to 128 and brightness values from 170 to 255.

24. The image processing apparatus of claim 22, further comprising: a histogram producing section for producing a three dimensional histogram of the obtained hue, saturation and brightness values and the brightness value distributing section and the color specification value distributing section are conducted based on the three dimensional histogram.

25. The image processing apparatus of claim 22, further comprising: a face region extracting section for extracting image data a face region from the captured image data, a contribution ratio determining section for determining a contribution ratio of the face region to a gradation converting section, and a gradation converting processing section for conducting a gradation converting section to the captured image data.

26. The image processing apparatus of claim 22, wherein the color specifying section acquires a hue value, a brightness value and a saturation value for every pixel of the captured image data and the face region extracting section extracts a region defined by predetermined hue and saturation values as the face region.

27. The image processing apparatus of claim 26, wherein the face region extracting section includes a histogram producing section for producing a two dimensional histogram of the obtained hue and saturation values and extracts the face region on the basis of the produced two dimensional histogram.

28. The image processing apparatus of claim 26, wherein the region defined by the predetermined hue and saturation values is a region defined by hue values from 0 to 50 and saturation values from 10 to 120 on the basis of the HSV color specification system.
